(19) United States
(12) Patent Application Publication
(10) Pub. No.: US 2026/0227697 A1
(43) Pub. Date: Aug. 6, 2026

(54) PHOTOREACTIVE COMPOUND, RESIST COMPOSITION INCLUDING THE SAME, PATTERN FORMATION METHOD USING THE RESIST COMPOSITION

(71) Applicant: Samsung Electronics Co., Ltd., Suwon-si (KR)

(72) Inventors: Dmitry ANDROSOV, Suwon-si (KR); Beomseok KIM, Suwon-si (KR); Hana KIM, Suwon-si (KR); Hyeran KIM, Suwon-si (KR); Hoyoon PARK, Suwon-si (KR); Kyuhyun IM, Suwon-si (KR)

(73) Assignee: Samsung Electronics Co., Ltd., Suwon-si, (KR)

(21) Appl. No.: 19/431,514

(22) Filed: Dec. 23, 2025

(30) Foreign Application Priority Data
Feb. 4, 2025 (KR) 10-2025-0013904

(51) Int. Cl. G03F 7/039; G03F 7/00; G03F 7/004

(52) U.S. Cl. CPC G03F 7/039; G03F 7/0045; G03F 7/70033

(57) ABSTRACT

Provided are a photoreactive compound represented by Formula 1 below, a resist composition including the same, and a pattern formation method using the resist composition:

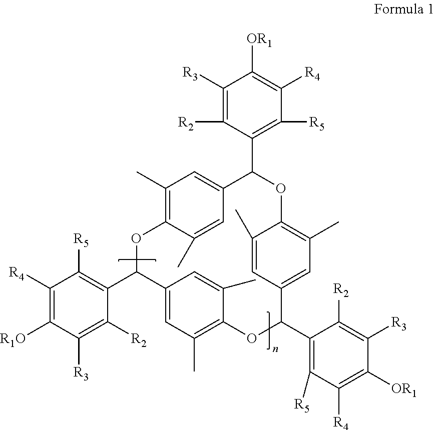

For a description of Formula 1, refer to the specification.

### CROSS-REFERENCE TO RELATED APPLICATION

This application is based on and claims priority under 35 U.S.C. § 119 to Korean Patent Application No. 10-2025-0013904, filed on Feb. 4, 2025, in the Korean Intellectual Property Office, the disclosure of which is incorporated by reference herein in its entirety.

### BACKGROUND

### 1. Field

The inventive concepts relate to photoreactive compounds, resist compositions including the same, and pattern formation methods using one or more of the resist compositions.

### 2. Description of the Related Art

During the manufacturing of semiconductors, photoresists having physical properties that change in response to light are being used to form fine patterns. Among these photoresists, chemically amplified photoresists have been widely used. In chemically amplified photoresists, acids formed when light (e.g., incident light having a particular intensity and/or wavelength) reacts with photoacid generators react again with base resins to change the solubility of the base resins in developers, thereby enabling patterning.

### SUMMARY

Provided are a resist composition of which physical properties are changed even upon exposure at a low dose and which provides a pattern with improved resolution, and a pattern formation method using the same. Based on a resist composition including the photoreactive compound represented by Formula 1, such a resist composition may be configured to reduce, minimize, or prevent the likelihood of a reduction in uniformity of patterns and/or an increase in surface roughness when the resist composition is used in a pattern formation method, for example based on avoiding such formed acid diffusion, while simultaneously providing improved resist composition thermal stability (and thereby reduced, minimized, or prevented risk of chemical deterioration) in normal usage environments at room temperature and/or while simultaneously changing physical properties even by exposure to a small amount (e.g., small intensity) of incident light (e.g., high-energy rays).

Additional aspects will be set forth in part in the description which follows and, in part, will be apparent from the description, or may be learned by practice of the presented embodiments of the inventive concepts.

According to some example embodiments of the inventive concepts, a photoreactive compound may be represented by Formula 1 below:

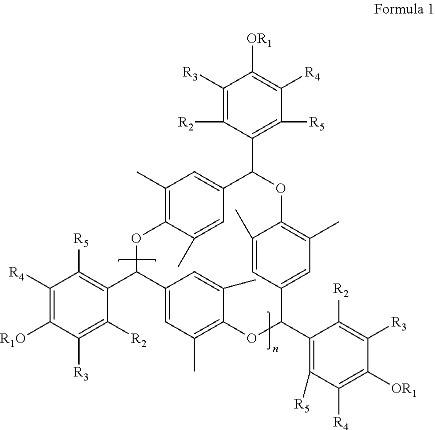

wherein, in Formula 1,
R₁ may be a photosensitive group or an acid-sensitive protecting group,
R₂ to R₅ may each independently be hydrogen; deuterium; a halogen; a cyano group; a nitro group; a hydroxy group; a C₁-C₃₀ monovalent hydrocarbon group optionally containing a heteroatom (e.g., one or more heteroatoms); a C₁-C₃₀ alkoxy group; a C₁-C₃₀ aryloxy group; a photosensitive group; or an acid-sensitive protecting group, and
n may be an integer from 1 to 10.

The photosensitive group may be reactive to visible light, ultraviolet (UV) rays, deep ultraviolet (DUV) rays, extreme ultraviolet (EUV) rays, electron beams (EBs), and/or X-rays.

The photosensitive group or the acid-sensitive protecting group may be a group represented by any one of -Tf, -Boc, and Formulas 2-1 to 2-25:

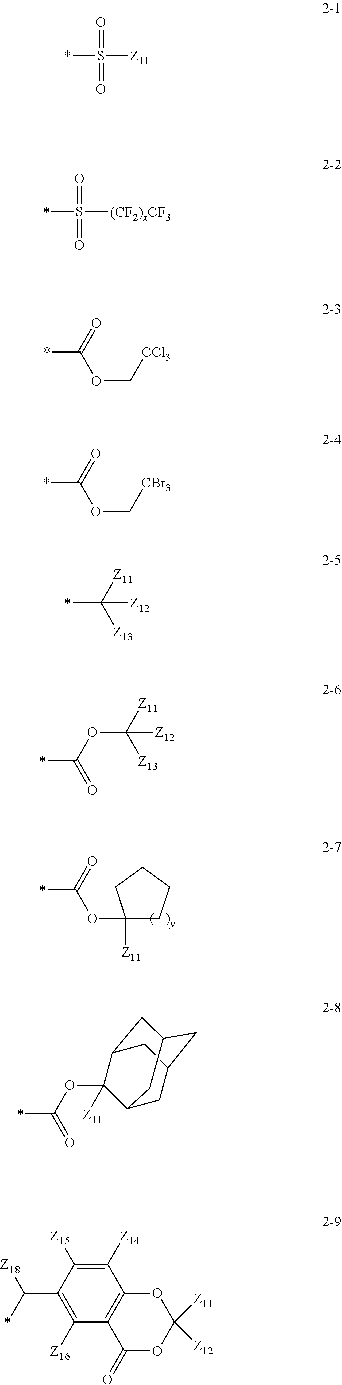

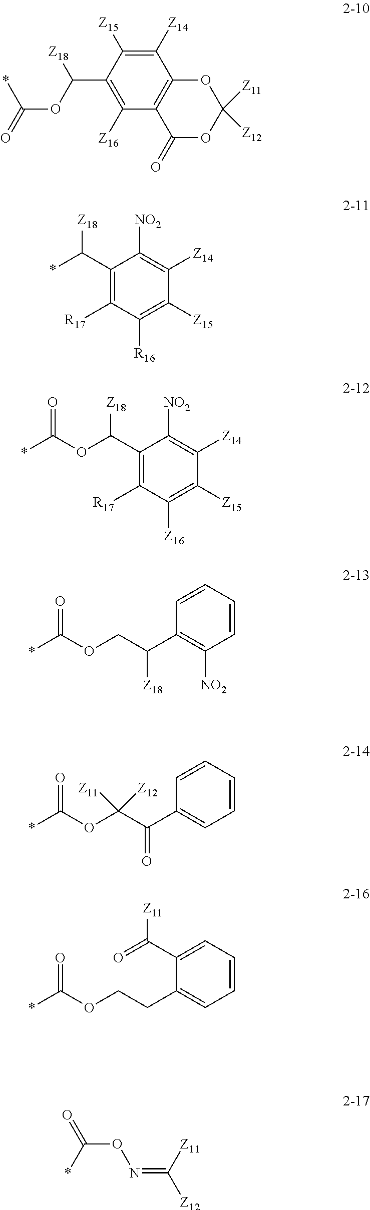

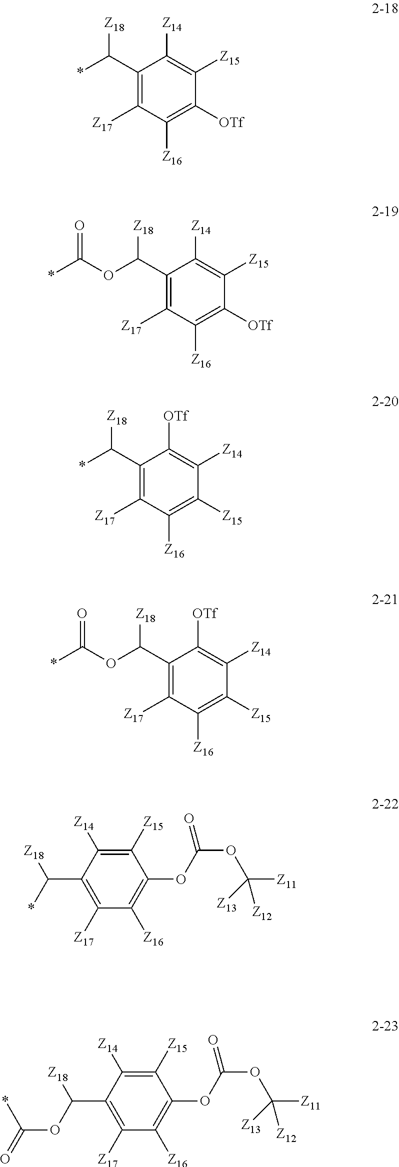

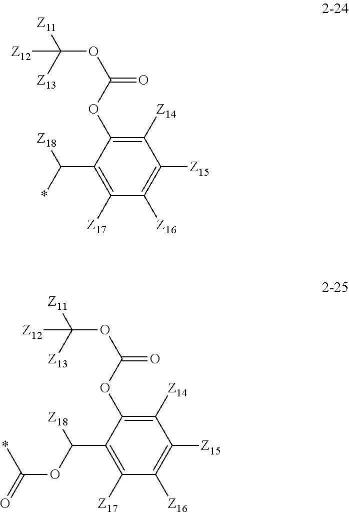

wherein, in Formulas 2-1 to 2-25,
Z₁₁ to Z₁₈ are each independently hydrogen; deuterium; a halogen; a cyano group; a nitro group; a hydroxy group; a C₁-C₃₀ monovalent hydrocarbon group optionally containing a heteroatom (e.g., one or more heteroatoms) and unsubstituted or substituted with a substituent; a C₁-C₃₀ alkoxy group unsubstituted or substituted with a substituent; a C₁-C₃₀ aryloxy group unsubstituted or substituted with a substituent; —CF₃; —OTf; —OMs; —OTos; or —OBoc,
R₁₆ and R₁₇ are each independently hydrogen; deuterium; a halogen; a cyano group; a nitro group; a hydroxy group; a C₁-C₃₀ monovalent hydrocarbon group optionally containing a heteroatom (e.g., one or more heteroatoms) and unsubstituted or substituted with a substituent; a C₁-C₃₀ alkoxy group unsubstituted or substituted with a substituent; a C₁-C₃₀ aryloxy group unsubstituted or substituted with a substituent; —CF₃; —OTf; —OMs; —OTos; or —OBoc,
Tf is a triflate (trifluoromethanesulfonate) group,
Ms is a mesyl group,
Tos is a tosyl group,
Boc is a tert-butoxycarbonyl group,
Ph is a phenyl group,
x is an integer from 1 to 10,
y is an integer from 1 to 10, and
* is a binding site with an adjacent atom of Formula 1.

In Formulas 2-1 to 2-25, Z₁₁ to Z₁₃ may each independently be selected from Formulas 3-1 to 3-36:

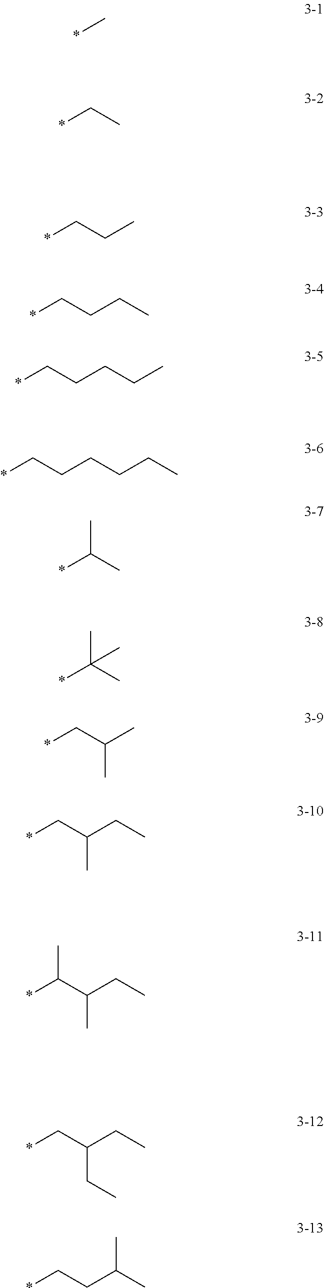

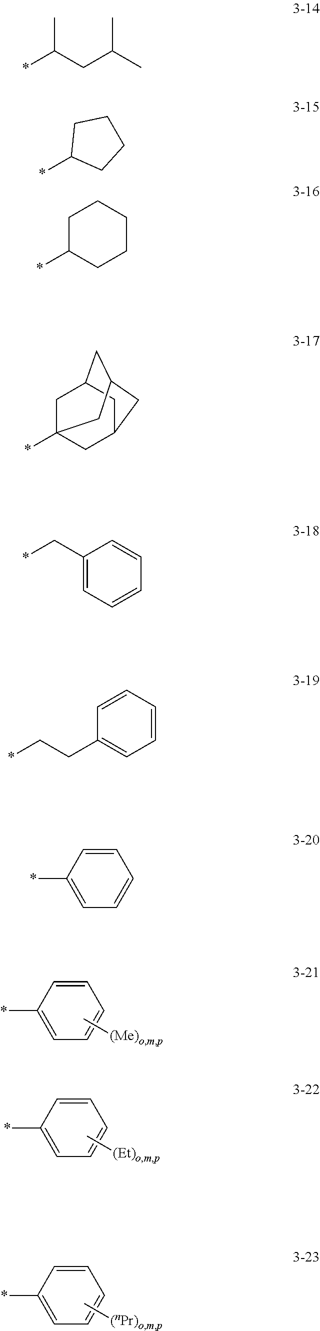

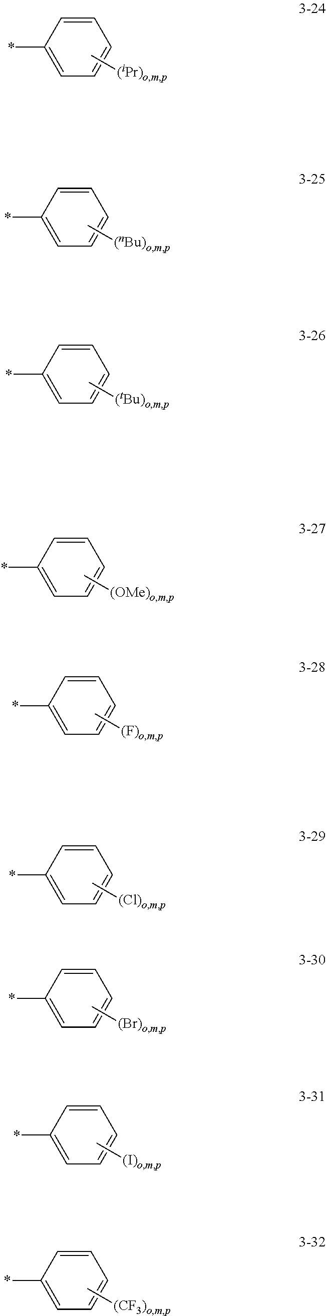

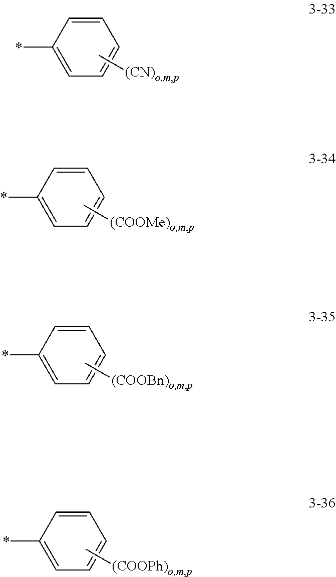

wherein, in Formulas 3-1 to 3-36,
* is a binding site with an adjacent atom,
o, m, p is one of an ortho position, a meta position, or a para position,
Me is a methyl group,
Et is an ethyl group,
ⁿPr is an n-propyl group,
ⁱPr is an isopropyl group,
ⁿBu is an n-butyl group,
^{t}Bu is a tert-butyl group,
Bn is a benzyl group, and
Ph is a phenyl group.

In Formulas 2-1 to 2-25, Z₁₄ to Z₁₇ and R₁₆ to R₁₇ may be selected from Formulas 4-1 to 4-46:

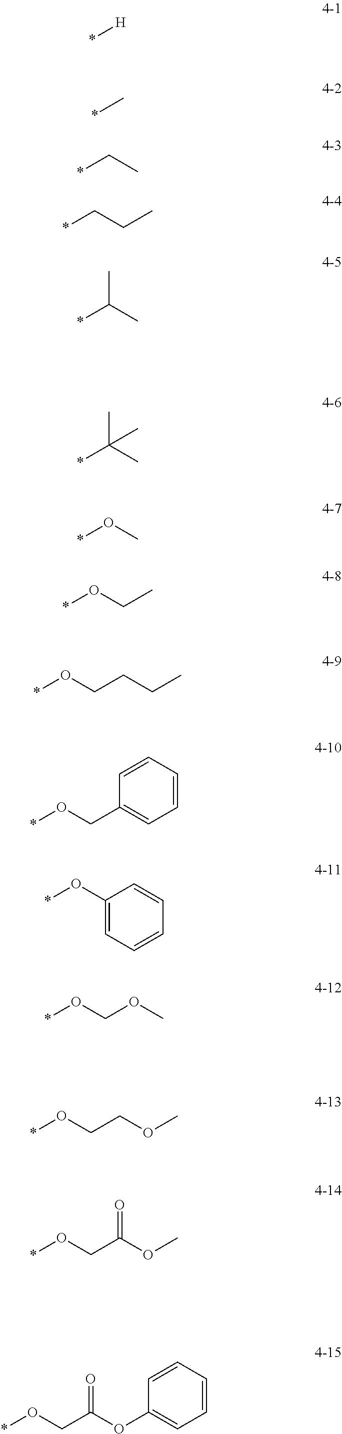

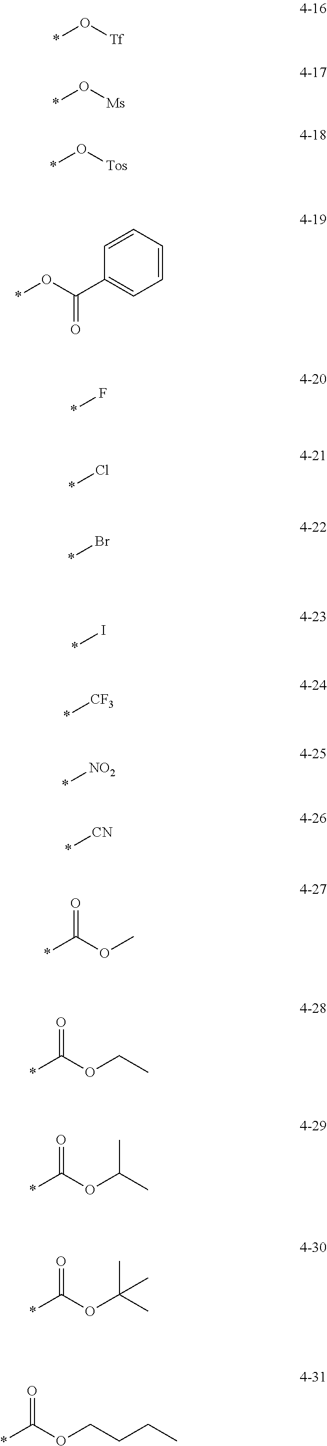

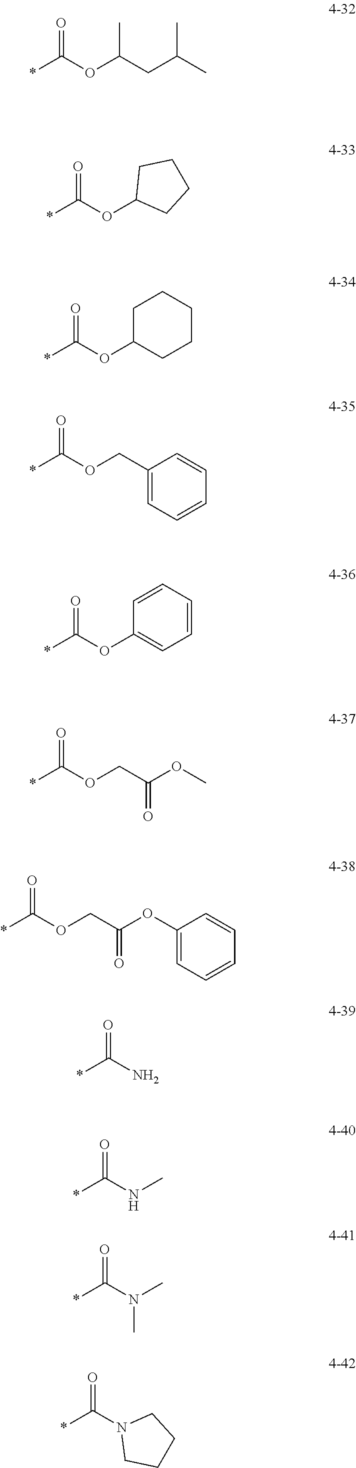

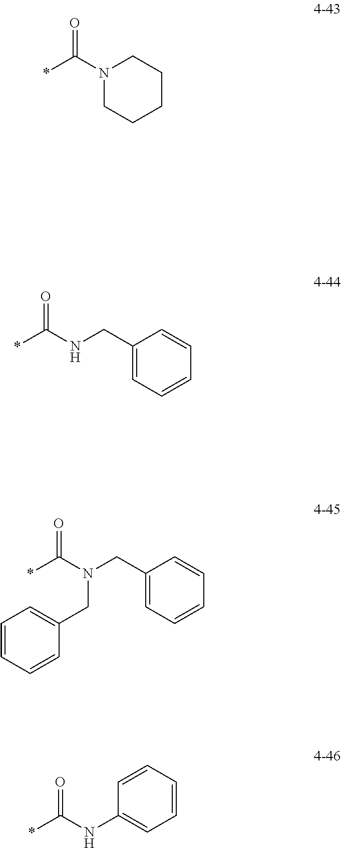

wherein, in Formulas 4-1 to 4-46,
* is a binding site with an adjacent atom,
Tf is a triflate (trifluoromethanesulfonate) group,
Ms is a mesyl group, and
Tos is a tosyl group.

In Formulas 2-1 to 2-25, Z₁₈ may be selected from Formulas 5-1 to 5-10:

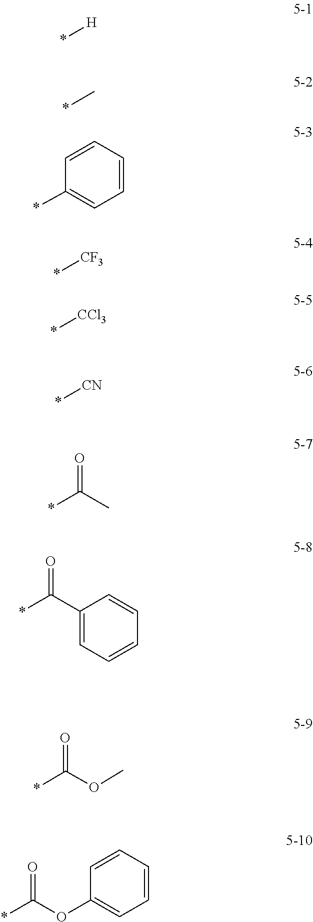

wherein, in Formulas 5-1 to 5-10, * is a binding site with an adjacent atom.

The photoreactive compound may have a weight average molecular weight of about 1,000 g/mol to about 3,000 g/mol.

The photoreactive compound may have a polydispersity index (PDI) of about 1 to about 1.5.

The photoreactive compound may have a glass transition temperature of 100° C. or more.

The photoreactive compound may have a 5% mass loss temperature (T_{d5%}) of 180° C. or more.

In Formula 1, n may be an integer from 1 to 5.

The photoreactive compound represented by Formula 1 may be selected from Group I:

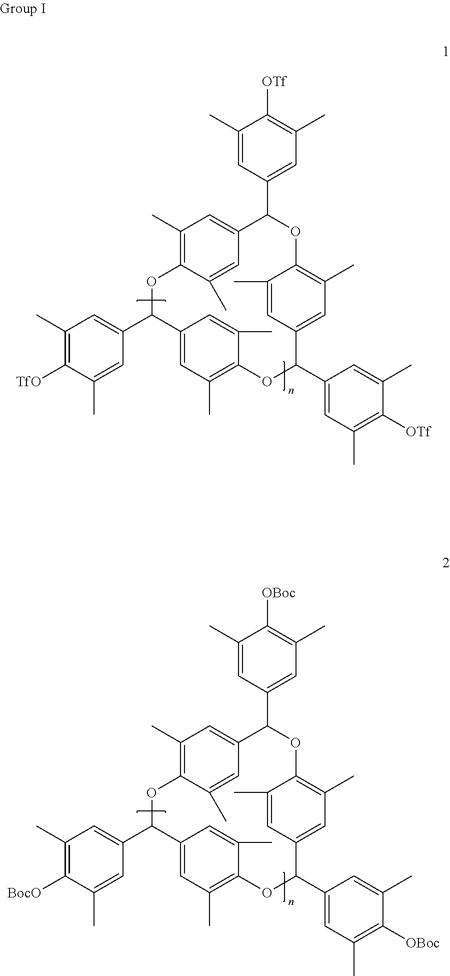

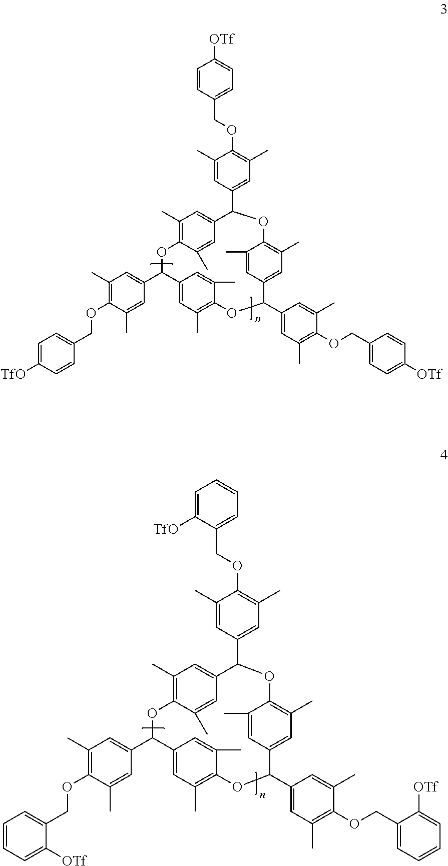

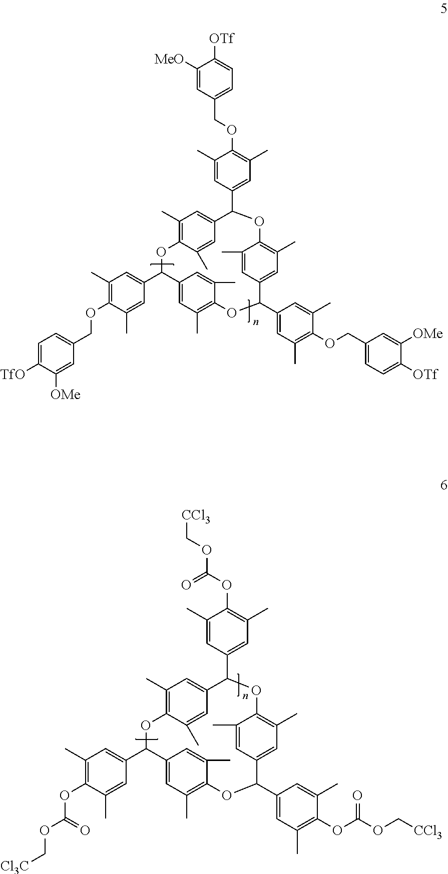

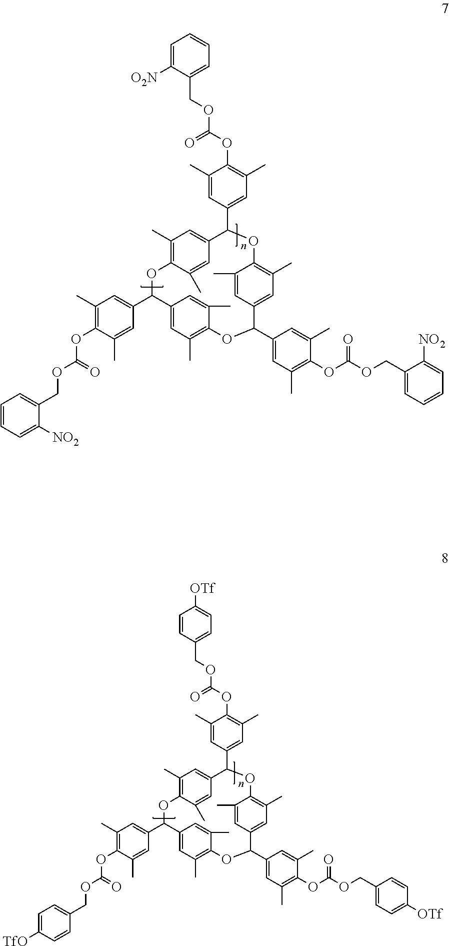

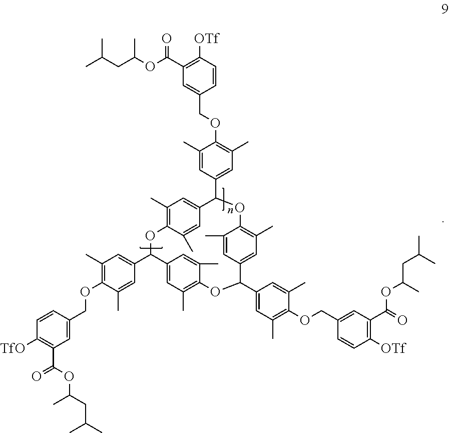

According to some example embodiments, a resist composition may include the photoreactive compound; and an organic solvent.

The resist composition may include a photoacid generator, a quencher, or any combination thereof.

The resist composition may not include any photoacid generator.

The resist composition may be a positive tone resist composition.

The resist composition may be a non-chemically amplified (non-CA) resist composition.

The photoreactive compound may be included in the resist composition in an amount of about 0.1 parts by weight to about 50 parts by weight with respect to 100 parts by weight of the resist composition.

According to some example embodiments, a pattern formation method may include applying the resist composition onto a substrate to form a resist film; exposing at least a portion of the resist film to high-energy rays to form an exposed resist film; and developing the exposed resist film based on using a developer.

The exposing may be performed based on irradiating ultraviolet (UV) rays, deep ultraviolet (DUV) rays, extreme ultraviolet (EUV) rays, and/or electron beams (Ebs).

### BRIEF DESCRIPTION OF THE DRAWINGS

The above and other aspects, features, and advantages of certain embodiments of the inventive concepts will be more apparent from the following description taken in conjunction with the accompanying drawings, in which:

FIG. 1 is a flowchart illustrating a pattern formation method according to some example embodiments;

FIGS. 2A, 2B, and 2C show side cross-sectional views illustrating a pattern formation method according to some example embodiments;

FIGS. 3A, 3B, 3C, 3D, and 3E are side cross-sectional views illustrating a method of forming a patterned structure, according to some example embodiments;

FIGS. 4A, 4B, 4C, 4D, and 4E are side cross-sectional views illustrating a method of forming a semiconductor device according to some example embodiments; and

FIGS. 5A, 5B, 5C, 5D, 5E, 5F, 5G, 5H, and 5I are diagrams showing ¹H-NMR data of Synthesis Examples 1 to 9, respectively, according to some example embodiments.

### DETAILED DESCRIPTION

Reference will now be made in detail to example embodiments, some of which are illustrated in the accompanying drawings, wherein like reference numerals refer to like elements throughout. In this regard, some example embodiments may have different forms and should not be construed as being limited to the descriptions set forth herein. Accordingly, some example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Since the present inventive concepts can apply various transformations and have various embodiments, specific embodiments will be illustrated in the drawings and described in detail in the detailed description. However, it should be understood that this is not intended to limit the inventive concepts to specific embodiments, and includes all transformations, equivalents, and substitutes included in the spirit and scope of the inventive concepts. In describing the inventive concepts, when it is determined that the specific description of the known related art unnecessarily obscures the gist of the inventive concepts, the detailed description thereof will be omitted.

The use of the term “the” and similar demonstratives may correspond to both the singular and the plural. Operations constituting methods may be performed in any suitable order unless otherwise indicated herein or otherwise clearly contradicted by context, and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

Regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Hereinafter, unless explicitly described to the contrary, it is to be understood that the terms such as “including,” “having,” and “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

As used herein, “Cₓ-C_{y}” or “Cx to Cy” means that a number (e.g., quantity) of carbons constituting a substituent is x to y, wherein x and y may each be any natural number. For example, “C₁-C₆” and “C1 to C6” means that a number of carbons constituting the substituent is 1 to 6, and “C₆-C₂₀” and C6 to C20” means that a number of carbons constituting the substituent is 6 to 20.

“ ” “ ” “ ” As used herein, the term “monovalent hydrocarbon group” may refer to a monovalent residue derived from an organic compound including carbon and hydrogen or a derivative thereof, and specific examples thereof may include: linear or branched alkyl groups (for example, a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); monovalent saturated cycloaliphatic hydrocarbon groups (cycloalkyl groups) (for example, a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and/or a dicyclohexylmethyl group); a monovalent unsaturated aliphatic hydrocarbon group (alkenyl group or alkynyl group) (for example, an allyl group); a monovalent unsaturated cycloaliphatic hydrocarbon group (cycloalkenyl group) (for example, 3-cyclohexenyl); aryl groups (for example, a phenyl group, a 1-naphthyl group, and/or a 2-naphthyl group); arylalkyl groups (for example, a benzyl group and a diphenylmethyl group); heteroatom-containing monovalent hydrocarbon groups (for example, a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and/or a 3-oxocyclohexyl group); or any combination thereof. In addition, in these groups, some hydrogen atoms may be substituted by a moiety including a heteroatom (e.g., one or more heteroatoms) such as an oxygen, sulfur, nitrogen, or halogen atom, or some carbon atoms may be substituted by a moiety including a heteroatom (e.g., one or more heteroatoms) such as oxygen, sulfur, or nitrogen so that the groups may include a hydroxy group, a cyano group, a carbonyl group, a carboxyl group, an ether bond, an ester bond, a sulfonate ester bond, carbonate, a lactone ring, a sultone ring, a carboxylic anhydride moiety, or a haloalkyl moiety.

As used herein, the term “divalent hydrocarbon group” is a divalent residue and means that any one hydrogen atom of the monovalent hydrocarbon group is replaced by a binding site to an adjacent atom. The divalent hydrocarbon group may include, for example, a linear or branched alkylene group, a cycloalkylene group, an alkenylene group, an alkynylene group, a cycloalkenylene group, an arylene group, a group in which some carbon atoms thereof are replaced with a heteroatom (e.g., one or more heteroatoms), and the like.

As used herein, the term “alkyl group” refers to a linear or branched saturated aliphatic hydrocarbon monovalent group, and specific examples thereof include a methyl group, an ethyl group, a propyl group, an isobutyl group, a sec-butyl group, a tert-butyl group, a pentyl group, an iso-amyl group, a hexyl group, and the like. As used herein, the term “alkylene group” refers to a linear or branched saturated aliphatic hydrocarbon divalent group, and specific examples thereof include a methylene group, an ethylene group, a propylene group, a butylene group, an isobutylene group, and the like.

As used herein, the term “halogenated alkyl group” refers to a group in which one or more substituents of an alkyl group are substituted with a halogen, and specific examples thereof include CF₃ and the like. Here, a halogen is F, Cl, Br, or I.

As used herein, the term “alkoxy group” refers to a monovalent group having a formula of —OA₁₀₁, wherein A₁₀₁ is an alkyl group. Specific examples thereof include a methoxy group, an ethoxy group, an isopropyloxy group, and the like.

As used herein, the term “alkylthio group” refers to a monovalent group having a formula of —SA₁₀₁, wherein A₁₀₁ is an alkyl group.

As used herein, the term “halogenated alkoxy group” refers to a group in which one or more hydrogen atoms of an alkoxy group are substituted with a halogen, and specific examples thereof include —OCF₃ and the like.

As used herein, the term “halogenated alkylthio group” refers to a group in which one or more hydrogen atoms of an alkylthio group are substituted with a halogen, and specific examples thereof include —SCF₃ and the like.

As used herein, the term “cycloalkyl group” refers to a monovalent saturated hydrocarbon cyclic group, and specific examples thereof include monocyclic groups such as a cyclopropyl group, a cyclobutyl group, a cyclopentyl group, a cyclohexyl group, and a cycloheptyl group, and polycyclic condensed cyclic groups such as a norbornyl group and an adamantyl group. As used herein, the term “cycloalkylene group” refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

As used herein, the term “cycloalkoxy group” refers to a monovalent group having a formula of —OA₁₀₂, wherein A₁₀₂ is a cycloalkyl group. Specific examples thereof include a cyclopropoxy group, a cyclobutoxy group, and the like.

As used herein, the term “cycloalkylthio group” refers to a monovalent group having a formula of —SA₁₀₂, wherein A₁₀₂ is a cycloalkyl group.

As used herein, the term “heterocycloalkyl group” may be a group in which some carbon atoms of the cycloalkyl group are replaced by a moiety including a heteroatom (e.g., one or more heteroatoms), for example, oxygen, sulfur, or nitrogen, and specifically, the heterocycloalkyl group may include an ether bond, an ester bond, a sulfonate ester bond, carbonate, a lactone ring, a sultone ring, or a carboxylic anhydride moiety. As used herein, the term “heterocycloalkylene group” is a group in which some carbon atoms of the cycloalkylene group are replaced by a moiety including a heteroatom (e.g., one or more heteroatoms), for example, oxygen, sulfur, or nitrogen.

As used herein, the term “heterocycloalkoxy group” refers to a monovalent group having a formula of —OA₁₀₃, wherein A₁₀₃ is a heterocycloalkyl group.

As used herein, the term “alkenyl group” refers to a linear or branched unsaturated aliphatic hydrocarbon monovalent group including one or more carbon-carbon double bonds. As used herein, the term “alkenylene group” refers to a linear or branched unsaturated aliphatic hydrocarbon divalent group including one or more carbon-carbon double bonds.

As used herein, the term “cycloalkenyl group” refers to a monovalent unsaturated hydrocarbon cyclic group including one or more carbon-carbon double bonds. As used herein, the term “cycloalkenylene group” refers to a divalent unsaturated hydrocarbon cyclic group including one or more carbon-carbon double bonds.

As used herein, the term “heterocycloalkenyl group” is a group in which some carbon atoms of the cycloalkenylene group are replaced by a moiety including a heteroatom (e.g., one or more heteroatoms), for example, oxygen, sulfur, or nitrogen. As used herein, the term “heterocycloalkenylene group” is a group in which some carbon atoms of the cycloalkenylene group are replaced by a moiety including a heteroatom (e.g., one or more heteroatoms), for example, oxygen, sulfur, or nitrogen.

As used herein, the term “alkynyl group” refers to a linear or branched unsaturated aliphatic hydrocarbon monovalent group including one or more carbon-carbon triple bonds.

As used herein, the term “aryl group” refers to a monovalent group having a carbocyclic aromatic system, and specific examples thereof include a phenyl group, a naphthyl group, an anthracenyl group, a phenanthrenyl group, a pyrenyl group, a chrysenyl group, and the like. As used herein, the term “arylene group” refers to a divalent group having a carbocyclic aromatic system.

As used herein, the term “heteroaryl group” refers to a monovalent group having a heterocyclic aromatic system, and specific examples thereof include a pyridinyl group, a pyrimidinyl group, a pyrazinyl group, and the like. As used herein, the term “heteroarylene group” refers to a divalent group having a heterocyclic aromatic system.

As used herein, the term “substituent” includes: deuterium, a halogen, a hydroxyl group, a cyano group, a nitro group, a carbonyl group, a carboxylate group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group;
a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with deuterium, a halogen, a hydroxyl group, a cyano group, a nitro group, a carbonyl group, a carboxylate group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, and any combination thereof; and any combination thereof.

As used herein, when a definition is not otherwise provided, “aromatic ring” refers to a functional group in which all atoms in the cyclic functional group have a p-orbital, and wherein these p-orbitals are conjugated.

Hereinafter, some example embodiments will be described in detail with reference to the accompanying drawings, wherein like reference numerals denote substantially the same or corresponding components throughout the drawings, and a redundant description thereof will be omitted. In the drawings, the thicknesses of layers and regions are exaggerated for clarity. Also, in the drawings, the thicknesses of some layers and regions are exaggerated for convenience of description. Meanwhile, example embodiments set forth herein are merely examples and various changes may be made therein.

### [Photoreactive Compound]

A photoreactive compound according to some example embodiments may be represented by Formula 1 below:

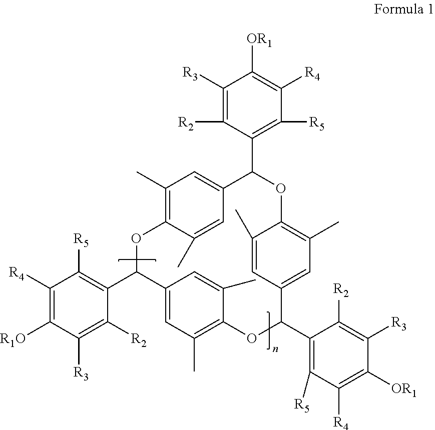

In Formula 1, R₁ may be a photosensitive group or an acid-sensitive protecting group.

In Formula 1, R₂ to R₅ may each independently be hydrogen; deuterium; a halogen; a cyano group; a nitro group; a hydroxy group; a C₁-C₃₀ monovalent hydrocarbon group optionally containing a heteroatom (e.g., one or more heteroatoms); a C₁-C₃₀ alkoxy group; a C₁-C₃₀ aryloxy group; a photosensitive group; or an acid-sensitive protecting group.

In Formula 1, n may be an integer from 1 to 10.

According to some example embodiments, n may be an integer from 1 to 5.

In some example embodiments, the photosensitive group may be reactive to visible light, ultraviolet (UV) rays, deep ultraviolet (DUV) rays, extreme ultraviolet (EUV) rays, electron beams (Ebs), and/or X-rays.

In some example embodiments, the photosensitive group may include an ester group, an amine group, a carbamate group, an acetamide group, a sulfonate group, a sulfate group, a sulfonamide group, an alkyl ether group, an allyl ether group, a silyl ether group, a benzyl ether group, a phenyl ether group, a phthalimide group, or any combination thereof.

According to some example embodiments, the photoreactive compound may undergo continuous depolymerization upon exposure to light.

In some example embodiments, the photosensitive group or acid-sensitive protecting group may be a group represented by any one of -Tf, -Boc, and Formulas 2-1 to 2-25 below:

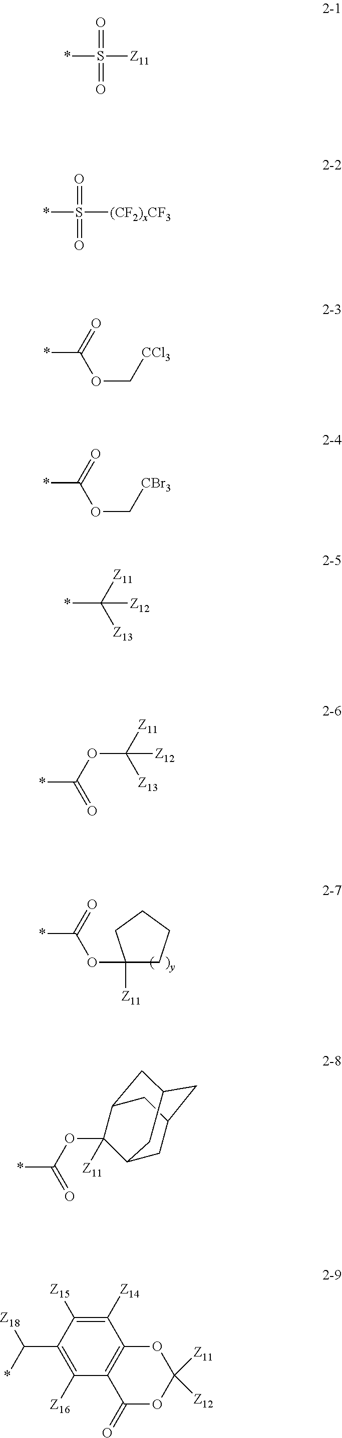

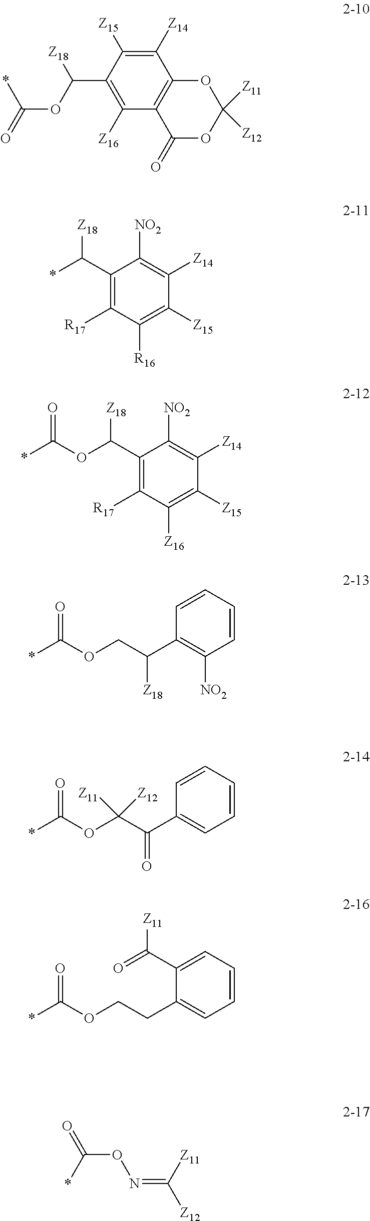

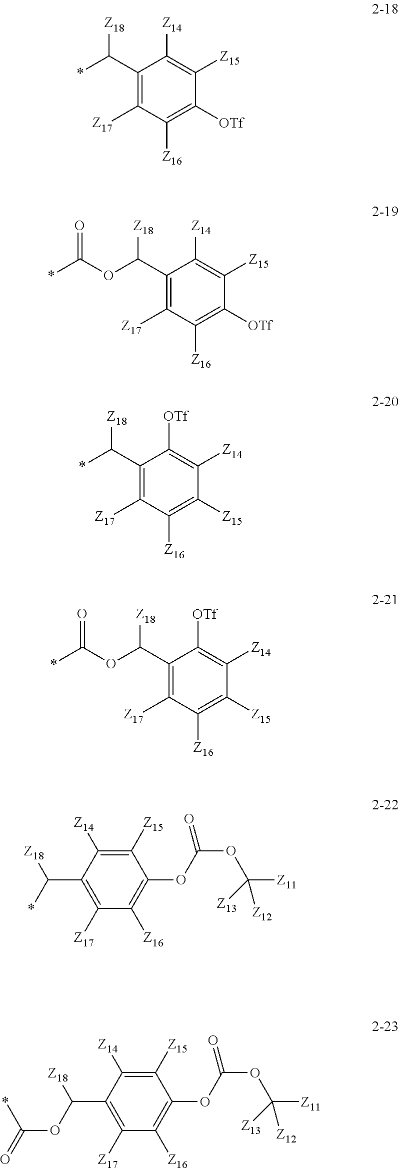

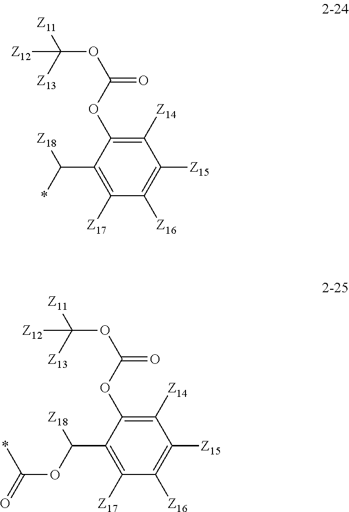

In Formulas 2-1 to 2-25,
Z₁₁ to Z₁₈ may each independently be hydrogen; deuterium; a halogen; a cyano group; a nitro group; a hydroxy group; a C₁-C₃₀ monovalent hydrocarbon group optionally containing a heteroatom (e.g., one or more heteroatoms) and unsubstituted or substituted with a substituent; a C₁-C₃₀ alkoxy group unsubstituted or substituted with a substituent; a C₁-C₃₀ aryloxy group unsubstituted or substituted with a substituent; —CF₃; —OTf; —OMs; —OTos; or —OBoc,
R₁₆ and R₁₇ may each independently be hydrogen; deuterium; a halogen; a cyano group; a nitro group; a hydroxy group; a C₁-C₃₀ monovalent hydrocarbon group optionally containing a heteroatom (e.g., one or more heteroatoms) and unsubstituted or substituted with a substituent; a C₁-C₃₀ alkoxy group unsubstituted or substituted with a substituent; a C₁-C₃₀ aryloxy group unsubstituted or substituted with a substituent; —CF₃; —OTf; —OMs; —OTos; or —OBoc,
Tf may be a triflate (trifluoromethanesulfonate) group,
Ms may be a mesyl group,
Tos may be a tosyl group,
Boc may be a tert-butoxycarbonyl group,
Ph may be a phenyl group,
x may be an integer from 1 to 10,
y may be an integer from 1 to 10, and
* may be is a binding site with an adjacent atom of Formula 1.

According to some example embodiments, R₁ may be a group represented by any one of -Tf, -Boc, and Formulas 2-1 to 2-25.

According to some example embodiments, in Formulas 2-1 to 2-25, Z₁₁ to Z₁₃ may each independently be selected from Formulas 3-1 to 3-36 below:

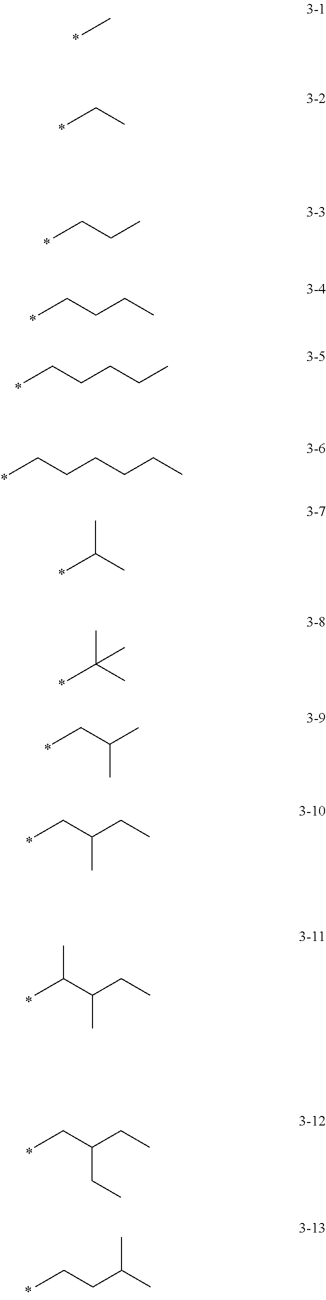

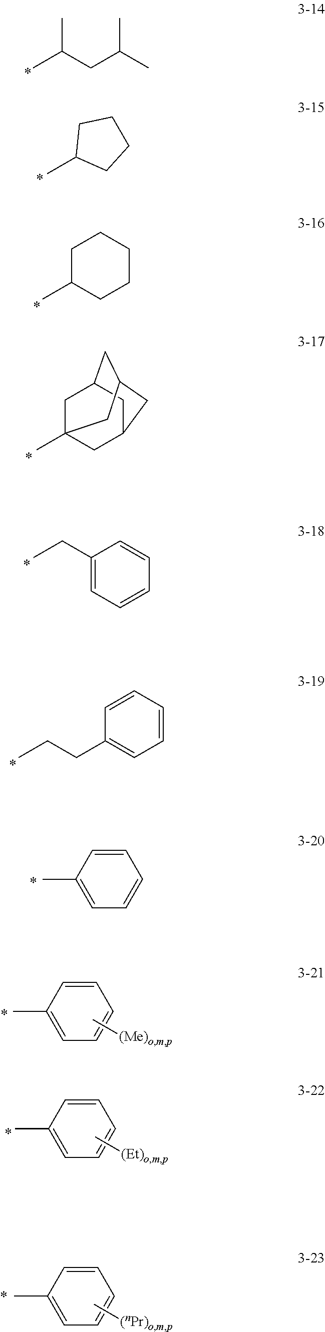

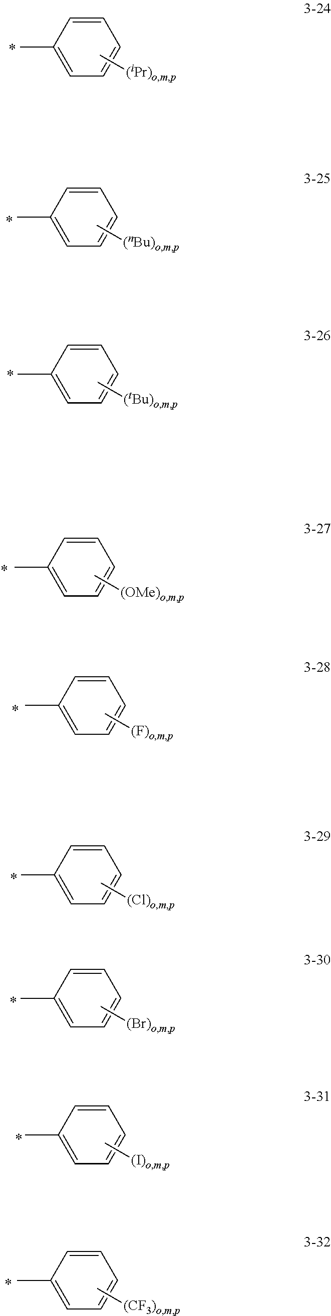

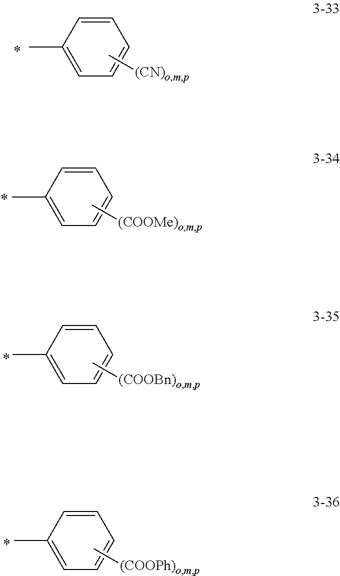

In Formulas 3-1 to 3-36,* may be a binding site with an adjacent atom (e.g., an adjacent atom of one of Formulas 2-1 to 2-25),
the recitation of a given functional group or substituent R as (R)_{o,m,p} indicates that the given functional group or substituent R is at an ortho position, a meta position, or a para position (e.g., in relation to the binding site *), such that “o, m, p” indicates one of an ortho position, a meta position, or a para position,
Me may be a methyl group,
Et may be an ethyl group,
ⁿPr may be an n-propyl group,
ⁱPr may be an isopropyl group,
ⁿBu may be an n-butyl group,
^{t}Bu may be a tert-butyl group,
Bn may be a benzyl group, and
Ph may be a phenyl group.

According to some example embodiments, in Formulas 2-1 to 2-25, Z₁₄ to Z₁₇ may be selected from Formulas 4-1 to 4-46 below:

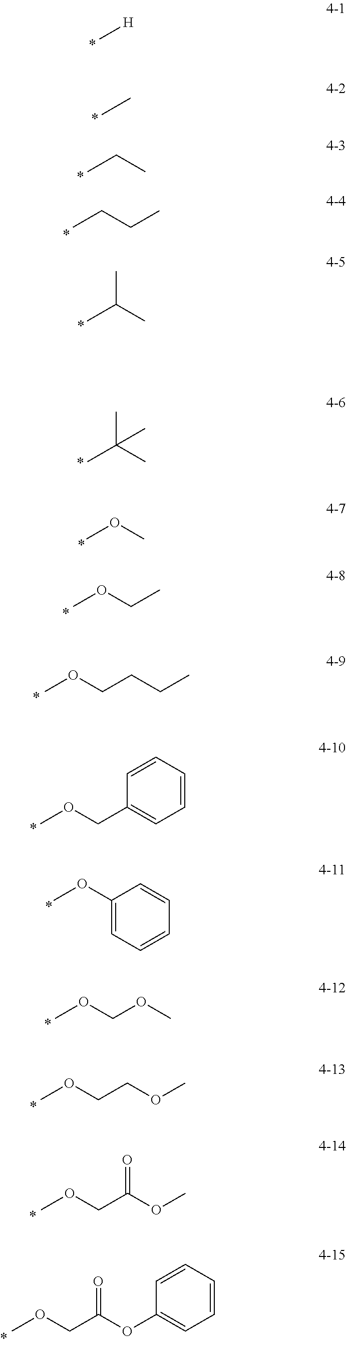

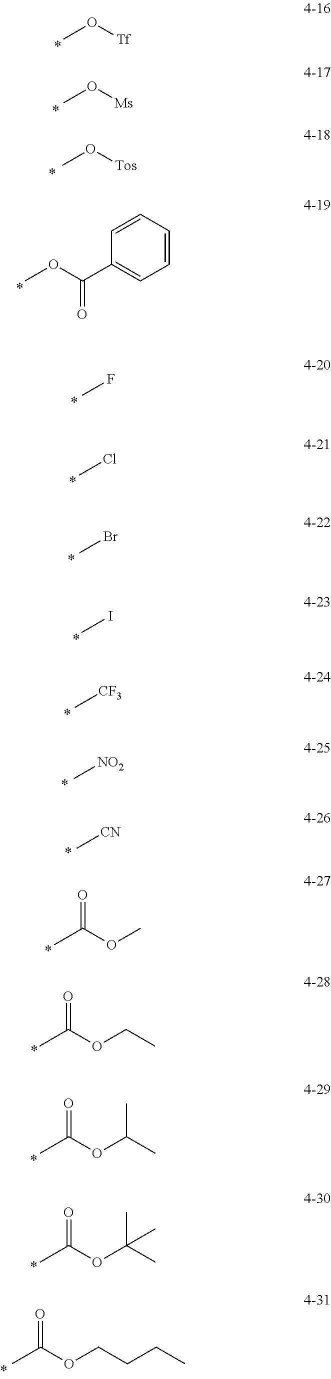

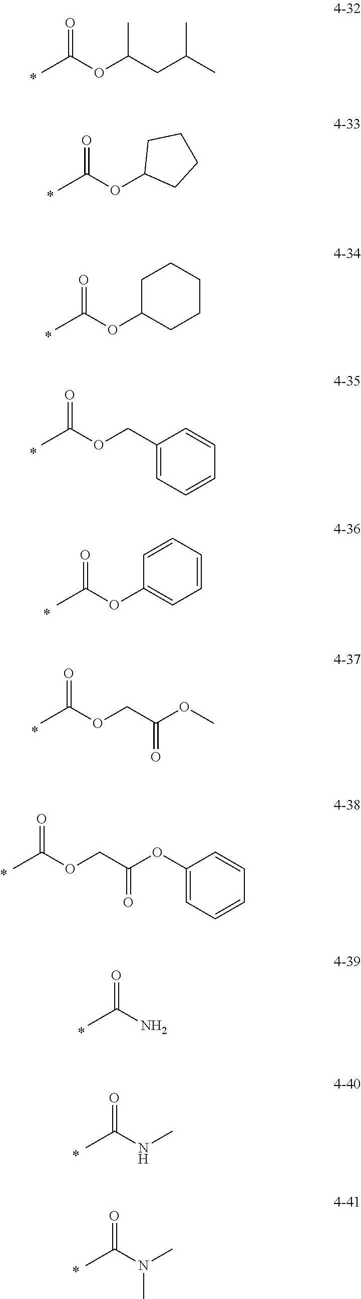

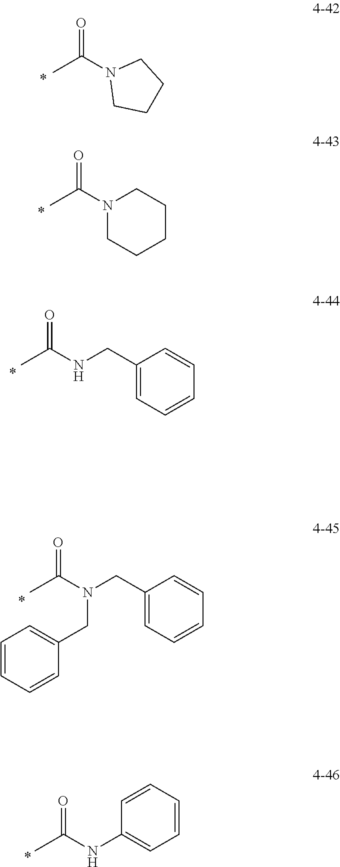

In Formulas 4-1 to 4-46, * may be a binding site with an adjacent atom (e.g., an adjacent atom of one of Formulas 2-1 to 2-25),
Tf may be a triflate (trifluoromethanesulfonate) group,
Ms may be a mesyl group, and
Tos may be a tosyl group.

According to some example embodiments, in Formulas 2-1 to 2-25, Z₁₈ may be selected from Formulas 5-1 to 5-10 below:

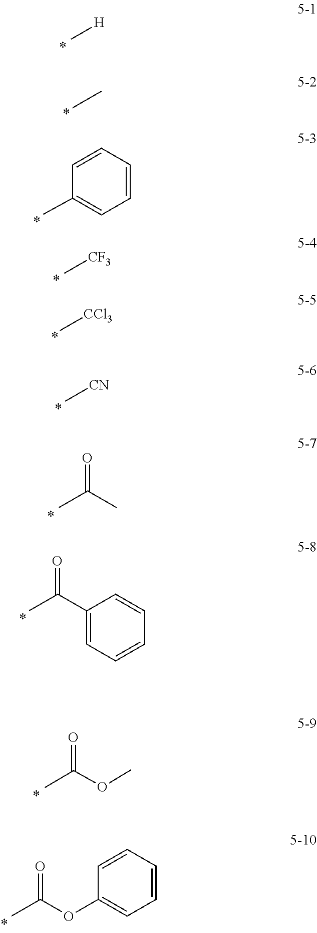

In Formulas 5-1 to 5-10, * may be a binding site with an adjacent atom (e.g., an adjacent atom of one of Formulas 2-1 to 2-25).

According to some example embodiments, a weight average molecular weight of the photoreactive compound may be in range of about 1,000 g/mol to about 3,000 g/mol, about 1,100 g/mol to about 2,900 g/mol, about 1,200 g/mol to about 2,800 g/mol, about 1,300 g/mol to about 2,700 g/mol, about 1,400 g/mol to about 2,600 g/mol, or about 1,400 g/mol to about 2,500 g/mol. In some example embodiments, the weight average molecular weight of the photoreactive compound may be equal to or greater than about 1,000 g/mol, about 1,100 g/mol, about 1,200 g/mol, about 1,300 g/mol, about 1,400 g/mol, about 1,400 g/mol, or any combination thereof. In some example embodiments, the weight average molecular weight of the photoreactive compound may be equal to or less than about 3,000 g/mol, about 2,900 g/mol, about 2,800 g/mol, about 2,700 g/mol, about 2,600 g/mol, about 2,500 g/mol, or any combination thereof.

According to some example embodiments, a glass transition temperature of the photoreactive compound may be 100° C. or more. For example, the glass transition temperature of the photoreactive compound may be 100° C. or more, 110° C. or more, or 120° C. or more. In some example embodiments, the glass transition temperature of the photoreactive compound may be equal to or less than 3000° C.

In some example embodiments, a 5% mass loss temperature T_{d5%} of the photoreactive compound may be 180° C. or more. For example, the 5% mass loss temperature of the photoreactive compound may be in a range of about 180° C. to about 300° C., about 190° C. to about 290° C., or about 200° C. to about 285° C.

In some example embodiments, a polydispersity index (PDI) of the photoreactive compound may in a range of about 1 to about 1.5.

In some example embodiments, the PDI (M_{w}/Mₙ, where M_{w} is the weight-average molar mass and Mₙ is the number-average molar mass) of the photoreactive compound may be in a range of about 1 to about 2, about 1 to about 1.5, about 1 to about 1.3, about 1 to about 1.1, or about 1 to about 1.05. When the above-described range is satisfied, it may be easy to control the dispersibility and/or compatibility of the photoreactive compound, a possibility of foreign materials remaining on a pattern may be reduced, or the deterioration of a pattern profile may be minimized. Accordingly, a resist composition may be more suitable for forming a fine pattern based on including the photoreactive compound. Based on a resist composition including the photoreactive compound represented by Formula 1, such a resist composition may be configured to reduce, minimize, or prevent the likelihood of a reduction in uniformity of patterns and/or an increase in surface roughness when the resist composition is used in a pattern formation method, for example based on avoiding such formed acid diffusion, while simultaneously providing improved resist composition thermal stability (and thereby reduced, minimized, or prevented risk of chemical deterioration) in normal usage environments at room temperature and/or while simultaneously changing physical properties even by exposure to a small amount (e.g., small intensity) of incident light (e.g., high-energy rays). Thereby, based on a resist composition including the photoreactive compound represented by Formula 1, such a resist composition may be configured to be used in a pattern formation method according to some example embodiments to enable the formation of a semiconductor device having improved pattern resolutions, thereby enabling miniaturization of semiconductor devices with improved device reliability based on the reduced likelihood of device defects due to reduced likelihood of defects resulting from low pattern resolution.

According to some example embodiments, the photoreactive compound may be selected from the Group I below:

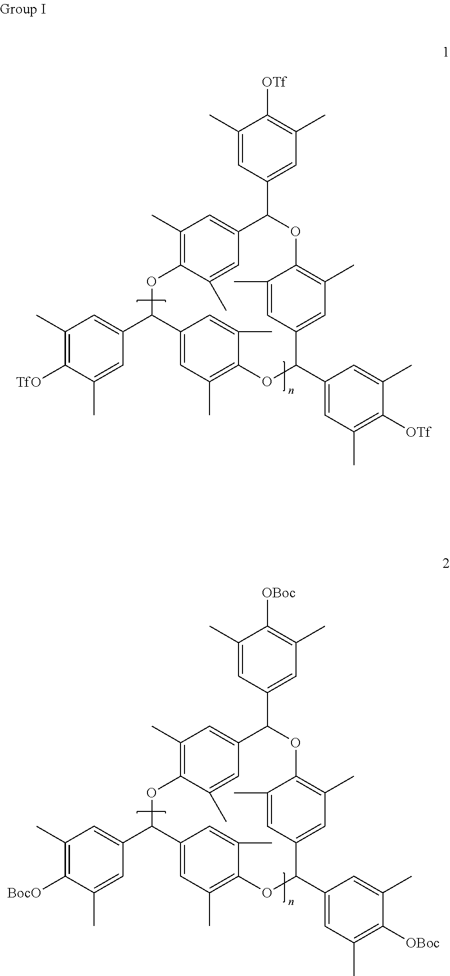

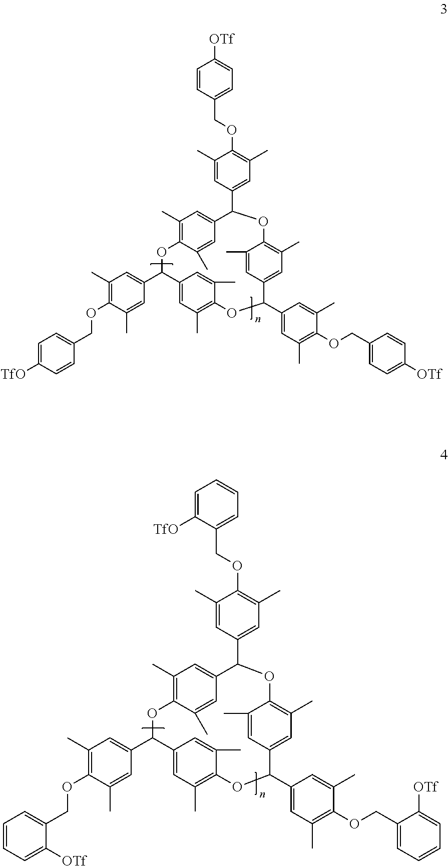

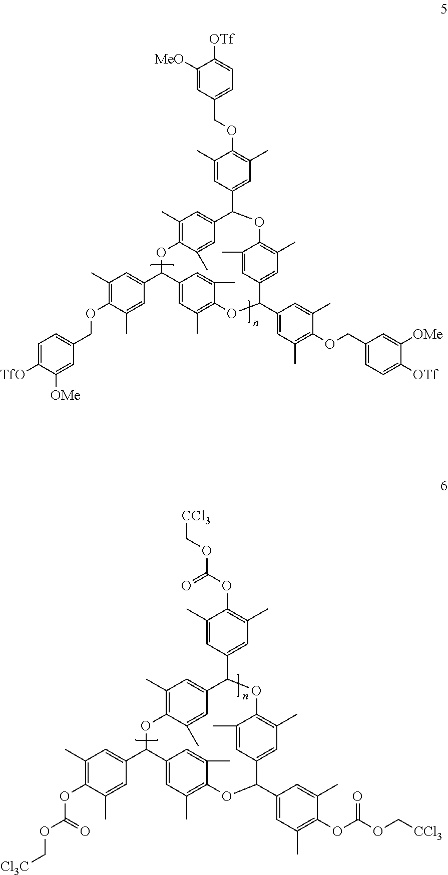

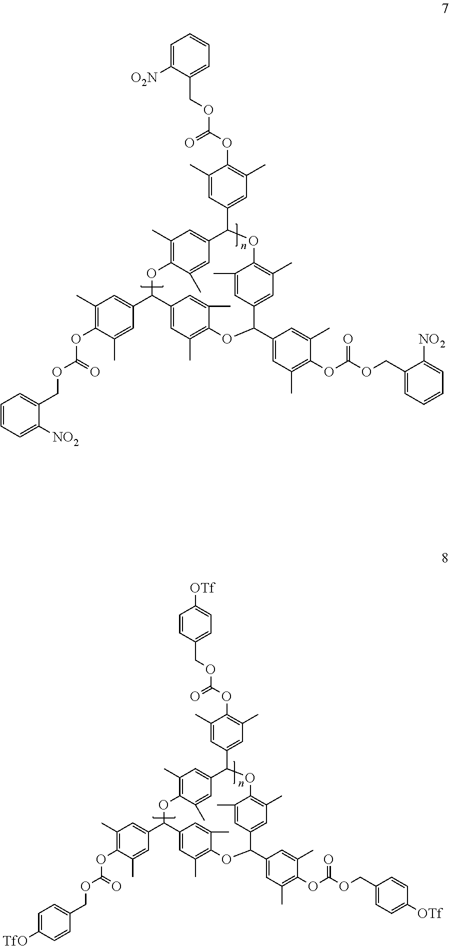

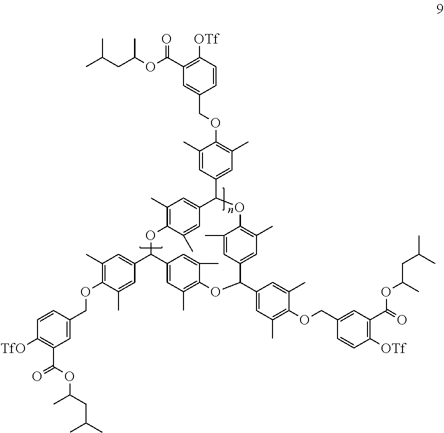

The photoreactive compound represented by Formula 1 may have improved (e.g., excellent) sensitivity to light exposure, a reduced and/or low PDI, and improved (excellent) thermal stability.

For example, the photoreactive compound represented by Formula 1 may have improved (e.g., excellent) sensitivity to EUV rays, and thus, when the photoreactive compound is applied to a resist, a high-resolution pattern with low line edge roughness (LER) may be efficiently obtained.

In addition, the photoreactive compound may have a low molecular weight and a low PDI and thus may have improved (e.g., excellent) solubility in a solvent, thereby forming a thin film with improved (e.g., excellent) quality.

Therefore, when a resist composition including the photoreactive compound represented by Formula 1 is used, since a treatment temperature range may be expanded in various process operations, the photoreactive compound may be advantageous for lithography applications.

Therefore, a resist composition including the photoreactive compound according to some example embodiments may have improved (e.g., excellent) properties such as improved developability and/or improved resolution.

In view of at least the above, the photoreactive compound may have a composition which may enable a resist composition including the photoreactive compound to be configured to reduce, minimize, or prevent the likelihood of a reduction in uniformity of patterns and/or an increase in surface roughness when the resist composition is used in a pattern formation method, based on avoiding such formed acid diffusion, while simultaneously providing improved resist composition thermal stability (and thereby reduced, minimized, or prevented risk of chemical deterioration) in normal usage environments at room temperature and/or while simultaneously changing physical properties even by exposure to a small amount (e.g., small intensity) of incident light (e.g., high-energy rays), based on the resist composition including the photoreactive compound represented by Formula 1. Thereby, based on a resist composition including the photoreactive compound represented by Formula 1, such a resist composition may be configured to be used in a pattern formation method according to some example embodiments to enable formation of a semiconductor device having improved pattern resolutions, thereby enabling miniaturization of semiconductor devices with improved device reliability based on the reduced likelihood of device defects due to reduced likelihood of defects resulting from low pattern resolution.

### [Resist Composition]

According to some example embodiments, there may be provided a resist composition including the above-described photoreactive compound (e.g., a photoreactive compound represented by Formula 1), and an organic solvent.

A base resin commonly used in a resist composition may have low LER due to a high PDI, chain entanglement, low compatibility with a photoacid generator and/or a solvent, or the like and thus may be disadvantageous in achieving a high-resolution pattern.

As described above, the photoreactive compound represented by Formula 1 may have improved (e.g., excellent) sensitivity to light exposure, a reduced or low PDI, and improved (e.g., excellent) thermal stability.

Therefore, the resist composition according to some example embodiments may have improved (e.g., excellent) properties such as improved developability and/or improved resolution based on including a photoreactive compound represented by Formula 1.

The resist composition may have properties such as improved photoreactivity and/or thermal stability based on including a photoreactive compound represented by Formula 1. As a result, the resist composition may be configured to reduce, minimize, or prevent the likelihood of a reduction in uniformity of patterns and/or an increase in surface roughness when the resist composition is used in a pattern formation method, for example based on avoiding such formed acid diffusion, while simultaneously providing improved resist composition thermal stability (and thereby reduced, minimized, or prevented risk of chemical deterioration) in normal usage environments at room temperature and/or while simultaneously changing physical properties even by exposure to a small amount (e.g., small intensity) of incident light (e.g., high-energy rays). Thereby, based on a resist composition including the photoreactive compound represented by Formula 1, such a resist composition may be configured to be used in a pattern formation method according to some example embodiments to enable the formation of a semiconductor device having improved pattern resolutions, thereby enabling miniaturization of semiconductor devices with improved device reliability based on the reduced likelihood of device defects due to reduced likelihood of defects resulting from low pattern resolution.

The solubility of the resist composition in a developer may be changed upon exposure to high-energy rays. The resist composition may be a positive type (positive tone) resist composition in which an exposed portion of a resist film is dissolved and removed to form a positive type resist pattern or may be a negative type resist composition in which an unexposed portion of a resist film is dissolved and removed to form a negative type resist pattern. In addition, a sensitive resist composition according to some example embodiments may be for an alkali developing process in which an alkali developer is used for developing treatment when a resist pattern is formed and may also be for a solvent developing process in which an organic solvent-containing developer (hereinafter referred to as an organic developer) is used for developing treatment.

In the resist composition, the photoreactive compound may be included in an amount of about 0.1 parts by weight to about 50 parts by weight, specifically, in an amount of 0.2 parts by weight or more, 0.5 parts by weight or more, 1 part by weight or more, 2 parts by weight or more, 30 parts by weight or less, or 20 parts by weight or less by weight, with respect to 100 parts by weight of the resist composition. When the above-described range is satisfied, while hydrogen bonds between photoreactive compounds are sufficiently formed, side reactions may be suppressed, thereby providing a resist composition having improved sensitivity and/or resolution and thus enabling formation of patterns (e.g., semiconductor patterns) having improved uniformity and/or reduced surface roughness.

The resist composition may be a non-chemically amplified (non-CA) resist composition.

### <Organic Solvent>

The resist composition may further include an organic solvent.

The organic solvent included in the resist composition is not particularly limited as long as the organic solvent may dissolve or disperse the photoreactive compound and any components included as needed. As the organic solvent, one type of an organic solvent may be used, or two or more different types of organic solvents may be used in combination.

Examples of the organic solvent may include, for example, an alcohol-based solvent, an ether-based solvent, a ketone-based solvent, an amide-based solvent, an ester-based solvent, a sulfoxide-based solvent, a hydrocarbon-based solvent, and the like.

More specifically, examples of the alcohol-based solvent may include a monoalcohol-based solvent such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, or diacetone alcohol; a polyhydric alcohol-based solvent such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, or tripropylene glycol; and a polyhydric alcohol-containing ether-based solvent such as ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, diethylene glycol dimethyl ether, propylene glycol monomethyl ether (PGME), propylene glycol dimethyl ether, propylene glycol monoethyl ether, propylene glycol monopropyl ether, propylene glycol monobutyl ether, dipropylene glycol monomethyl ether, dipropylene glycol monoethyl ether, or dipropylene glycol monopropyl ether.

Examples of the ether-based solvent may include: a dialkyl ether-based solvent such as diethyl ether, dipropyl ether, or dibutyl ether; a cyclic ether-based solvent such as tetrahydrofuran or tetrahydropyran; and an aromatic ring-containing ether-based solvent such as diphenyl ether or anisole.

Examples of the ketone-based solvent may include: a chain ketone-based solvent such as acetone, methyl ethyl ketone, methyl n-propyl ketone, methyl n-butyl ketone, diethyl ketone, methyl iso-butyl ketone, 2-heptanone, ethyl-n-butyl ketone, methyl-n-hexyl ketone, diisobutyl ketone, or trimethylnonanone; a cyclic ketone-based solvent such as cyclopentanone, cyclohexanone, cycloheptanone, cyclooctanone, or methylcyclohexanone; and 2,4-pentanedione, acetonyl acetone, and acetophenone.

Examples of the amide-based solvent may include: a cyclic amide-based solvent such as N,N′-dimethylimidazolidinone or N-methyl-2-pyrrolidone; and a chain amide-based solvent such as N-methylformamide, N,N-dimethylformamide, N,N-diethylformamide, acetamide, N-methylacetamide, N,N-dimethylacetamide, or N-methylpropionamide.

Examples of the ester-based solvent may include: an acetate ester-based solvent such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, or n-nonyl acetate; a polyhydric alcohol-containing ether carboxylate-based solvent such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, or dipropylene glycol monoethyl ether acetate; a lactone-based solvent such as γ-butyrolactone or δ-valerolactone; a carbonate-based solvent such as dimethyl carbonate, diethyl carbonate, ethylene carbonate, or propylene carbonate; a lactate ester-based solvent such as methyl lactate, ethyl lactate (EL), n-butyl lactate, or n-amyl lactate; and glycoldiacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, or diethyl phthalate.

Examples of the sulfoxide-based solvent may include dimethyl sulfoxide, diethyl sulfoxide, and the like.

Examples of the hydrocarbon-based solvent may include: an aliphatic hydrocarbon-based solvent such as n-pentane, isopentane, n-hexane, isohexane, n-heptane, isoheptane, 2,2,4-trimethylpentane, n-octane, isooctane, cyclohexane, or methylcyclohexane; and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, or n-amylnaphthalene.

Specifically, the organic solvent may be selected from an alcohol-based solvent, an amide-based solvent, an ester-based solvent, a sulfoxide-based solvent, and any combination thereof. More specifically, the organic solvent may be selected from PGME, propylene glycol monoethyl ether, PGMEA, N-methyl-2-pyrrolidone, N,N-dimethylacetamide, EL, dimethyl sulfoxide, and any combination thereof.

Meanwhile, when an acid labile group in the form of acetal is used, in order to accelerate a deprotection reaction of acetal, high-boiling alcohol such as diethylene glycol, propylene glycol, glycerol, 1,4-butanediol, or 1,3-butanediol may be further added to the organic solvent.

The organic solvent may be used in an amount of about 200 parts by weight to about 5,000 parts by weight, specifically, about 400 parts by weight to about 3,000 parts by weight, with respect to 100 parts by weight of the photoreactive compound.

### <Photoacid Generator>

The photoacid generator may be any compound capable of generating an acid when exposed to high-energy rays such as UV rays, DUV rays, EBs, EUV rays, X-rays, α-rays, or γ-rays.

The photoacid generator may include at least one selected from a sulfonium salt, an iodonium salt, and any combination thereof.

The resist composition according to some example embodiments may not include any or substantially any photoacid generators. Accordingly, LER of the resist composition may be lowered so that pattern resolution may be improved.

A resist composition according to some example embodiments may include a photoacid generator.

In some example embodiments, the photoacid generator may be represented by Formula 7 below:

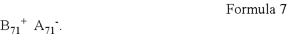

In Formula 7,

B₇₁⁺ may be represented by Formula 7A below, A₇₁⁻ may be represented by any one of Formulas 7B to 7D below, and

B₇₁⁺ and A₇₁⁻ may be optionally linked to each other through a carbon-carbon covalent bond:

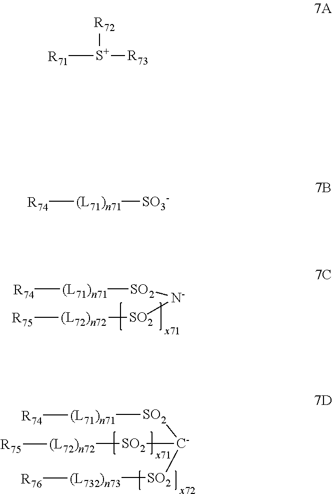

In Formulas 7A to 7D,
L₇₁ to L₇₃ and L₇₃₂ may each independently be a single bond or CRR′,
R and R′ may each independently be hydrogen, deuterium, a halogen, a cyano group, a hydroxy group, a C₁-C₃₀ alkyl group, a C₁-C₃₀ halogenated alkyl group, a C₁-C₃₀ alkoxy group, a C₃-C₃₀ cycloalkyl group, or a C₃-C₃₀ cycloalkoxy group,
n71 to n73 may each independently be 1, 2, or 3,
x71 and x72 may each independently be 0 or 1,
R₇₁ to R₇₃ may each independently be a linear, branched, or cyclic C₁-C₃₀ monovalent hydrocarbon group,
adjacent two of R₇₁ to R₇₃ may be optionally bonded to each other to form a ring, and
R₇₄ to R₇₆ may each independently be hydrogen, a halogen, or a linear, branched, or cyclic C₁-C₃₀ monovalent hydrocarbon group optionally containing a heteroatom (e.g., one or more heteroatoms).

For example, in Formula 7, B₇₁⁺ may be represented by Formula 7A, and A₇₁⁻ may be represented by Formula 7B. Specifically, in Formula 7A, R₇₁ to R₇₃ may each be a phenyl group.

The photoacid generator may be included in an amount of about 0 parts by weight to about 40 parts by weight, about 0.1 parts by weight to about 40 parts by weight, or about 0.1 parts by weight to about 20 parts by weight with respect to 100 parts by weight of the photoreactive compound. When the above-described range is satisfied, appropriate resolution may be achieved, and problems related to foreign material particles after developing or during stripping may be reduced.

As the photoacid generator, one type of a photoacid generator may be used, or two or more different types of photoacid generators may be mixed and used.

### <Quencher>

The quencher may be a salt that generates an acid having a lower acidity than an acid generated from a photoacid generator.

The quencher may include at least one selected from an ammonium salt, a sulfonium salt, an iodonium salt, and any combination thereof.

In some example embodiments, the quencher may be represented by Formula 8 below:

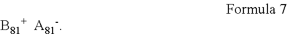

In Formula 8,
B₈₁⁺ may be represented by any one of Formulas 8A to 8C below, A₈₁⁻ may be represented by any one of Formulas 8D to 8F below, and
B₈₁⁺ and A₈₁⁻ may be optionally linked to each other through a carbon-carbon covalent bond,

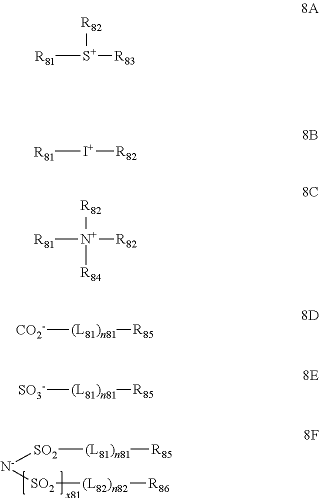

In Formulas 8A to 8F,
L₈₁ and L₈₂ may each independently be a single bond or CRR′,
R and R′ may each independently be hydrogen, deuterium, a halogen, a cyano group, a hydroxy group, a C₁-C₃₀ alkyl group, a C₁-C₂₀ halogenated alkyl group, a C₁-C₃₀ alkoxy group, a C₃-C₃₀ cycloalkyl group, or a C₃-C₃₀ cycloalkoxy group,
n81 and n82 may each independently be 1, 2, or 3,
x81 may be 0 or 1,
R₈₁ to R₈₄ may each independently be hydrogen, a halogen, or a linear, branched, or cyclic C₁-C₃₀ monovalent hydrocarbon group optionally containing a heteroatom (e.g., one or more heteroatoms),
adjacent two of R₈₁ to R₈₄ may be optionally bonded to each other to form a ring, and
R₈₅ and R₈₆ may each be hydrogen, a halogen, or a linear, branched, or cyclic C₁-C₃₀ monovalent hydrocarbon group optionally containing a heteroatom (e.g., one or more heteroatoms).

The quencher may be included in an amount of about 0.01 parts by weight to about 10 parts by weight, about 0.05 parts by weight to about 5 parts by weight, or about 0.1 parts by weight to about 3 parts by weight with respect to 100 parts by weight of the photoreactive compound. When the above-described range is satisfied, appropriate resolution may be achieved, and problems related to foreign material particles after developing or during stripping may be reduced.

As the quencher, one type of a quencher may be used, or two or more different types of quenchers may be mixed and used.

### <Optional Components>

The resist composition may further include a surfactant, a crosslinking agent, a leveling agent, a colorant, or any combination thereof as necessary.

The resist composition may further include a surfactant to improve coatability, developability, and the like. A specific example of the surfactant may include, for example, a nonionic surfactant such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, or polyethylene glycol distearate. As the surfactant, a commercially available product or a synthetic product may be used. Examples of the commercially available product of the surfactant may include KP341 (manufactured by Shin-Etsu Chemical Co., Ltd.), Polyflow No. 75 and Polyflow No. 95 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (products manufactured by DIC Corporation), Fluorad™ FC430 and Fluorad™ FC431 (manufactured by Sumitomo 3M, Ltd.), Asahi Guard™ AG710 (manufactured by AGC Seimi Chemical Co., Ltd.), and Surflon™ S-382, Surflon™ SC-101, Surflon™ SC-102, Surflon™ SC-103, Surflon™ SC-104, Surflon™ SC-105, and Surflon™ SC-106 (manufactured by AGC Seimi Chemical Co., Ltd.).

The surfactant may be included in an amount of about 0 parts by weight to about 20 parts by weight with respect to 100 parts by weight of the photoreactive compound. As the surfactant, one type of a surfactant may be used, or two or more different types of surfactants may be mixed and used.

A method of preparing the resist composition is not particularly limited, and for example, a method of mixing the photoreactive compound, the photoacid generator, and any components added as needed in an organic solvent may be used. A temperature or time during mixing is not particularly limited. If necessary, filtration may be performed after mixing.

### [Pattern Formation Method]

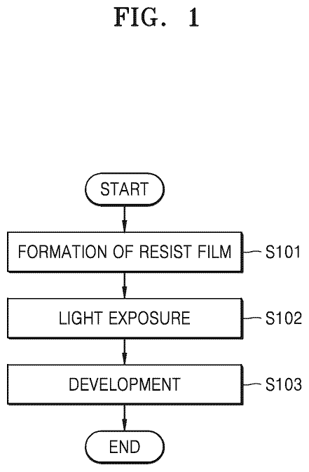

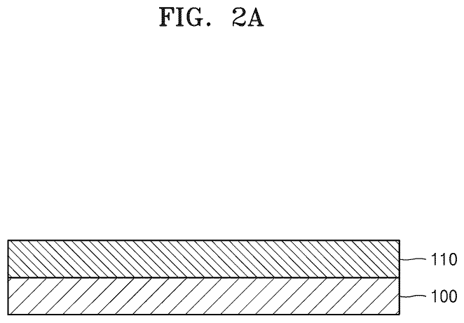

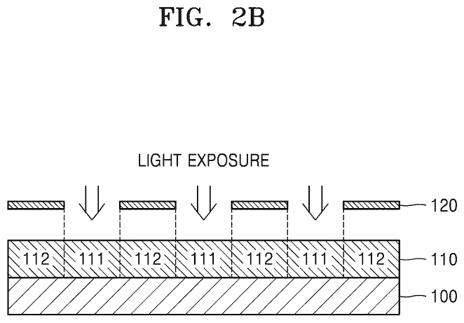

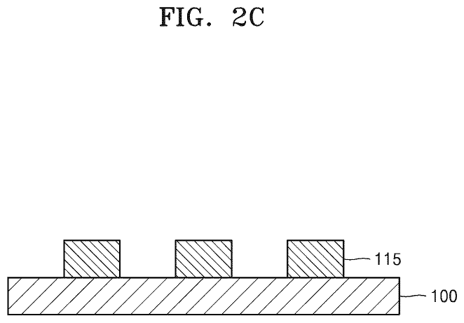

Hereinafter, a pattern formation method according to some example embodiments will be described in more detail with reference to FIGS. 1, 2A, 2B, and 2C. FIG. 1 is a flowchart illustrating the pattern formation method according to some example embodiments, and FIGS. 2A, 2B, and 2C show side cross-sectional views illustrating the pattern formation method according to some example embodiments. Hereinafter, an example of a pattern formation method using a negative resist composition will be described in detail, but the inventive concepts are not limited thereto.

Referring to FIG. 1, the pattern formation method may include operation S101 of applying a resist composition to form a resist film, operation S102 of exposing at least a portion of the resist film to high-energy rays to form an exposed resist film, and operation S103 of developing the exposed resist film based on using a developer. Such operations may be omitted if necessary or may be performed in a different order.

First, referring to FIG. 1 and FIG. 2A, a substrate 100 may be prepared. The substrate 100 may include, for example, a semiconductor substrate such as a silicon substrate or a germanium substrate, glass, quartz, ceramic, or copper. In some example embodiments, the substrate 100 may include a Group III-V compound such as GaP, GaAs, or GaSb.

The resist composition may be applied to a desired thickness onto the substrate 100, specifically, through a coating method, to form a resist film 110. The applied resist composition may be the resist composition as described herein according to any of the example embodiments. Accordingly, the resist film 110 may include the resist composition according to any of the example embodiments. If necessary, heating (prebaking (PB)) may be performed to remove an organic solvent remaining on the resist film 110. In some example embodiments, the resist film 110 may be heated to generate radicals, and then the radicals may be chemically bonded through exposure to form a crosslink.

As the coating method, spin coating, dipping, roller coating, or other general coating methods may be used. Among the coating methods, in particular, spin coating may be used, and the viscosity, concentration, and/or spin speed of the resist composition may be adjusted to form the resist film 110 having a desired thickness. Specifically, the resist film 110 may have a thickness of about 10 nm to about 300 nm. More specifically, the resist film 110 may have a thickness of about 30 nm to about 200 nm.

A lower limit of a temperature of the PB may be 60° C. or more, specifically, 80° C. or more. In some example embodiments, an upper limit of the temperature of the PB may be 150° C. or less, specifically, 140° C. or less. A lower limit of a time of the PB may be 5 seconds or more, specifically, 10 seconds or more. An upper limit of the time of the PB may be 600 seconds or less, specifically, 300 seconds or less.

Before the resist composition is applied onto the substrate 100, an etching target film (not shown) may be further formed on the substrate 100. The etching target film may refer to a layer on which an image is transferred from a resist pattern and converted into a certain pattern. In some example embodiments, the etching target film may be formed to include, for example, an insulating material such as silicon oxide, silicon nitride, or silicon oxynitride. In some example embodiments, the etching target film may be formed to include a conductive material such as a metal, a metal nitride, a metal silicide, or a metal silicide nitride. In some example embodiments, the etching target film may be formed to include a semiconductor material such as polysilicon.

In some example embodiments, an antireflection film may be further formed on the substrate 100 to increase or maximize the efficiency of a resist. The antireflection film may be an organic or inorganic antireflection film.

In some example embodiments, a protective film may be further provided on the resist film 110 to reduce the influence of alkaline impurities or the like included during a process. In addition, when immersion exposure is performed, for example, a protective film for immersion may also be provided on the resist film 110 to avoid direct contact between an immersion medium and the resist film 110.

Next, referring to FIG. 1 and FIG. 2B, at least a portion of the resist film 110 may be exposed to high-energy rays, thereby establishing an exposed resist film. For example, high-energy rays passing through a mask 120 may be irradiated onto at least a portion of the resist film 110. Thus, based on the exposing, the resist film 110 (e.g., the exposed resist film) may have an exposed portion 111 and an unexposed portion 112.

Although not limited to a specific theory, radicals may be generated in the exposed portion 111 through exposure, and chemical bonds may be formed between the radicals so that the physical properties of the resist composition may be changed.

In some example embodiments, the exposure may be performed by irradiating high-energy rays through a mask 120 with a certain pattern by using a liquid such as water as a medium. Examples of the high-energy rays may include electromagnetic waves such as UV rays, DUV rays, EUV rays (with a wavelength of 13.5 nm), X-rays, and γ-rays; and charged particle beams such as EBs and a rays. Irradiating the high-energy rays may be collectively referred to as “exposure.”

Examples of an exposure light source may include various light sources such as a light source that emits laser light in a UV region, such as a KrF excimer laser (with a wavelength of 248 nm), an ArF excimer laser (with a wavelength of 193 nm), or an F₂ excimer laser (with a wavelength of 157 nm), a light source that converts a wavelength of laser light from a solid-state laser light source (yttrium aluminum garnet (YAG) or semiconductor laser or the like) to emit harmonic laser light in a far UV or vacuum UV region, and a light source that irradiates EBs or EUV rays. During exposure, the exposure may be usually performed through a mask corresponding to a desired pattern, but when exposure light is an EB, the exposure may be performed through direct writing without using a mask.

Regarding an integral dose of high-energy rays, for example, when EUV rays are used as the high-energy rays, the integral dose may be 2,000 mJ/cm² or less, specifically, 500 mJ/cm² or less and may be greater than 0 mJ/cm², for example 0.01 mJ/cm² or more, for example 0.1 mJ/cm² or more, for example 1 mJ/cm² or more. In addition, when EBs are used as the high-energy rays, the integral dose may be 5,000 μC/cm² or less, specifically, 1,000 μC/cm² or less and may be greater than 0 mJ/cm², for example 0.01 mJ/cm² or more, for example 0.1 mJ/cm² or more, for example 1 mJ/cm² or more.

In addition, post-exposure baking (PEB) may be performed after the exposure. A lower limit of a temperature of the PEB may be 50° C. or more, specifically, 80° C. or more. An upper limit of the temperature of the PEB may be 250° C. or less, specifically, 200° C. or less. A lower limit of a time of the PEB may be 5 seconds or more, specifically, 10 seconds or more. An upper limit of the time of the PEB may be 600 seconds or less, specifically, 300 seconds or less.

Next, referring to FIG. 1 and FIG. 2C, the exposed resist film 110 may be developed by using a developer. The unexposed portion 112 may be washed away by the developer, and the exposed portion 111 may remain unwashed away by the developer. The resultant structure as shown in FIG. 2C may be and/or may define a resist pattern 115.

Examples of the developer may include an alkaline developer and a developer including an organic solvent (hereinafter also referred to as “organic developer”). Examples of a developing method may include a dipping method, a puddle method, a spray method, a dynamic injection method, and the like. A developing temperature may be, for example, in a range of about 5° C. to about 60° C., and a developing time may be, for example, in a range of about 5 seconds to about 300 seconds.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethyl ammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkaline developer may further include a surfactant.

A lower limit of a content of the alkaline compound in the alkaline developer may be 0.1 wt % or more, specifically, 0.5 wt % or more, or more specifically, 1 wt % or more. In addition, an upper limit of the content of the alkaline compound in the alkaline developer may be 20 wt % or less, specifically, 10 wt % or less, or more specifically, 5 wt % or less.

Examples of the organic solvent included in the organic developer may include the same organic solvent as those exemplified in the part of <Organic solvent> of [Resist composition].

A lower limit of a content of the organic solvent in the organic developer may be 80 wt % or more, specifically, 90 wt % or more, more specifically, 95 wt % or more, or particularly, 99 wt % or more.

The organic developer may also include a surfactant. In addition, a trace amount of water may be included in the organic developer. Furthermore, during developing, the developing may be stopped by substituting the organic developer with a solvent that is a different type therefrom.

A resist pattern after the developing may be further cleaned. Ultrapure water, a rinse solution, or the like may be used as a cleaning solution. A rinse solution is not particularly limited as long as the rinse solution does not dissolve a resist pattern, and a solution including a general organic solvent may be used. For example, the rinse solution may be an alcohol-based solvent or an ester-based solvent. After the cleaning, the rinse solution remaining on the substrate 100 and a pattern may be removed. In addition, when ultrapure water is used, water remaining on the substrate 100 and the pattern may be removed.

In some example embodiments, developers may be used singly or in a combination of two or more.

After the resist pattern is formed as described above, a pattern interconnection substrate may be obtained through etching. The etching may be performed through a known method including dry etching using plasma gas and wet etching using an alkaline solution, a copper (II) chloride solution, an iron (II) chloride solution, or the like.

After the resist pattern is formed, plating may be performed. The plating is not particularly limited, and examples thereof may include copper plating, solder plating, nickel plating, gold plating, and the like.

The resist pattern remaining after the etching may be peeled off with an organic solvent. One or more embodiments are not limited thereto, but examples of such an organic solvent may include PGMEA, PGME, EL, and the like. A peeling method is not particularly limited, but examples thereof may include an immersion method, a spray method, and the like. In addition, the pattern interconnection substrate on which the resist pattern is formed may be a multi-layer interconnection substrate or may have small-diameter through-holes.

In some example embodiments, the pattern interconnection substrate may be formed through a method of forming a resist pattern, depositing a metal in a vacuum, and then melting the resist pattern with a solution, that is, a lift-off method.

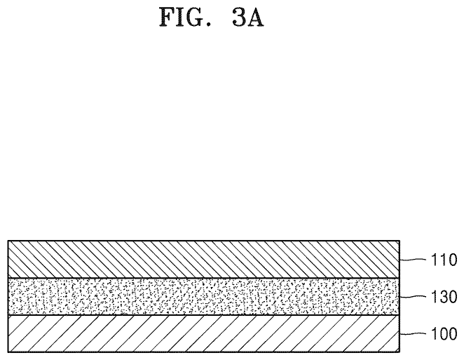

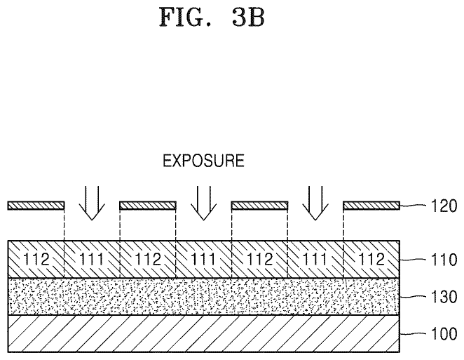

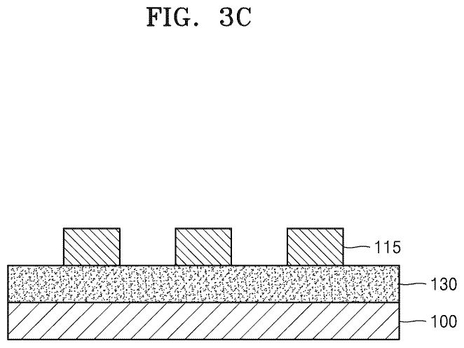

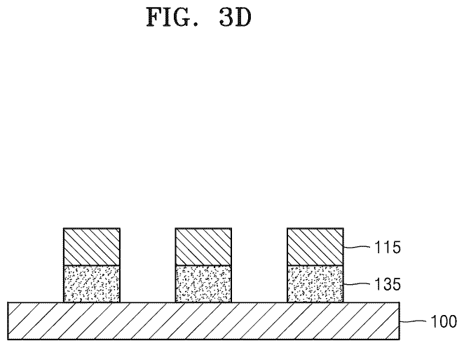

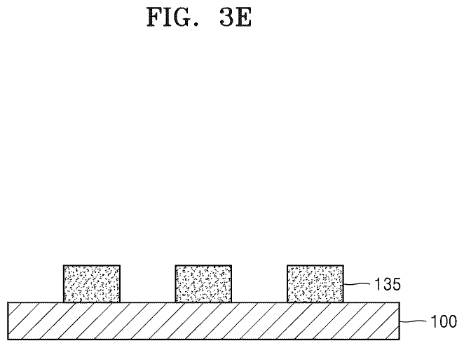

FIGS. 3A, 3B, 3C, 3D, and 3E are side cross-sectional views illustrating a method of forming a patterned structure according to some example embodiments.

As shown in FIG. 3A, a material layer 130 may be formed on a substrate 100 before forming a resist film 110 on the substrate 100. The resist film 110 may be formed on the material layer 130. The material layer 130 may include an insulating material (e.g., silicon oxide, silicon nitride), a semiconductor material (e.g., silicon), or a metal (e.g., copper). In some example embodiments, the material layer 130 may have a multilayer structure. The material of the material layer 130 may be different from the material of the substrate 100.

As shown in FIG. 3B, the resist film 110 may be exposed to high-energy rays through a mask 120 after undergoing a prebake process before exposure, and then the resist film 110 may include an exposed portion 111 and an unexposed portion 112.

As shown in FIG. 3C, the exposed resist film 110 may be developed by using a developer (e.g., a developing solution). The unexposed portion 112 may be washed away by the developer, and the exposed portion 111 may remain without being washed away by the developer to define the resist pattern 115.

As shown in FIG. 3D, a material pattern 135 may be formed on a substrate 100 by etching an exposed portion of a material layer 130 using a resist pattern 115 as a mask.

As shown in FIG. 3E, the resist pattern 115 may be removed.

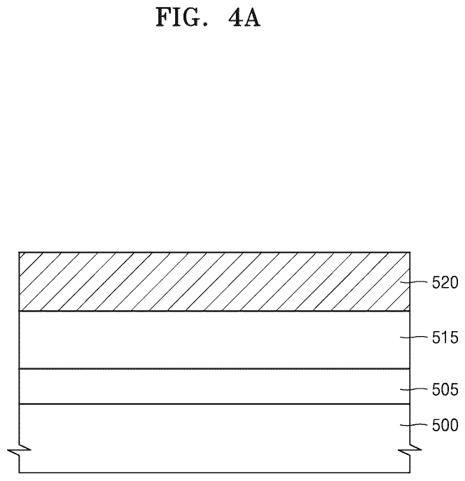

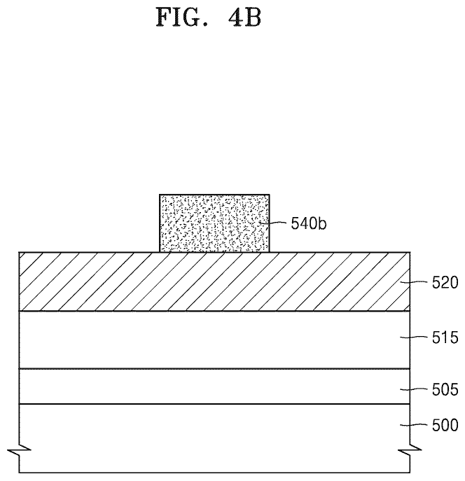

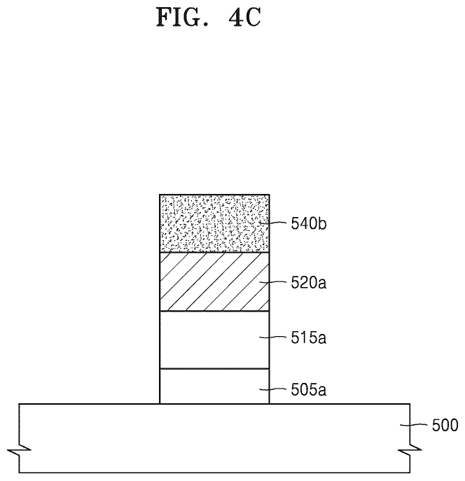

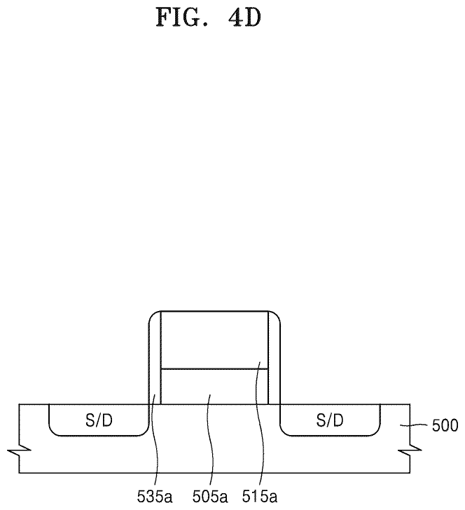

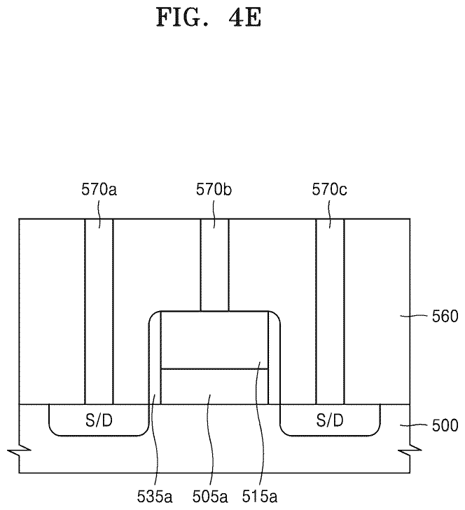

FIGS. 4A, 4B, 4C, 4D, and 4E are side cross-sectional views illustrating a method of forming a semiconductor device according to some example embodiments.

As shown in FIG. 4A, a gate dielectric 505 (e.g., silicon oxide) may be formed on a substrate 500. The substrate 500 may be a semiconductor substrate such as a silicon substrate. A gate layer 515 (e.g., doped polysilicon) may be formed on the gate dielectric 505. A hardmask layer 520 may be formed on the gate layer 515.

As shown in FIG. 4B, a resist pattern 540b may be formed on the hardmask layer 520. A resist pattern 540b may be formed using a resist composition according to some example embodiments. The resist composition may include an organic solvent.

As shown in FIG. 4C, the gate layer 515 and the gate dielectric 505 may be etched to form a hardmask pattern 520a, a gate electrode pattern 515a, and a gate dielectric pattern 505a.

As shown in FIG. 4D, a spacer layer may be formed on the gate electrode pattern 515a and the gate dielectric pattern 505a. The spacer layer may be formed using a deposition process (e.g., chemical vapor deposition (CVD)). The spacer layer may be etched to form a spacers 535a (e.g., silicon nitride) on sidewalls of the gate electrode pattern 515a and the gate dielectric pattern 505a. After forming the spacers 535a, ions may be implanted into the substrate 500 to form source/drain impurity regions S/D.

As shown FIG. 4E, an interlayer insulating layer 560 (e.g., oxide) may be formed on the substrate 500 to cover the gate electrode pattern 515a, the gate dielectric pattern 505a, and the spacers 535a. Then, electrical contacts 570a, 570b, and 570c connected to the gate electrode pattern 515a and the S/D regions may be formed in the interlayer insulating layer 560. The electrical contacts 570a, 570b, and 570c may be formed of a conductive material (e.g., metal). Although not shown, a barrier layer may be formed between sidewalls of the interlayer insulating layer 560 and the electrical contacts 570a, 570b, and 570c.

While FIGS. 4A to 4E illustrate an example of forming a transistor, the inventive concepts are not limited thereto.

A resist composition according to some example embodiments may be used in a patterning process to form other types of semiconductor devices.

The inventive concepts will be described in more detail using the following Examples and Comparative Examples, but the technical scope of the inventive concepts is not limited only to the following Examples.

### EXAMPLES

### Synthesis Example 1: Synthesis of Compound 1

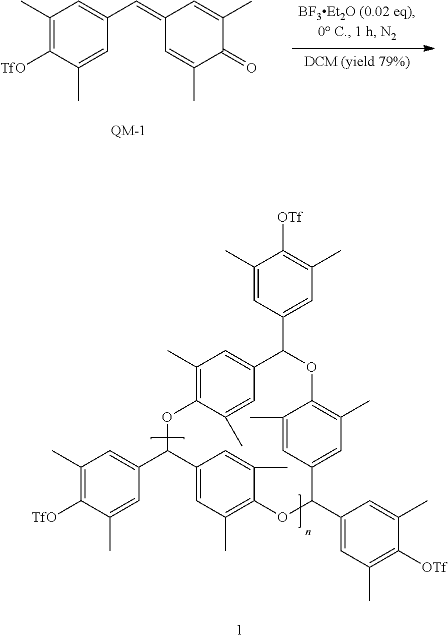

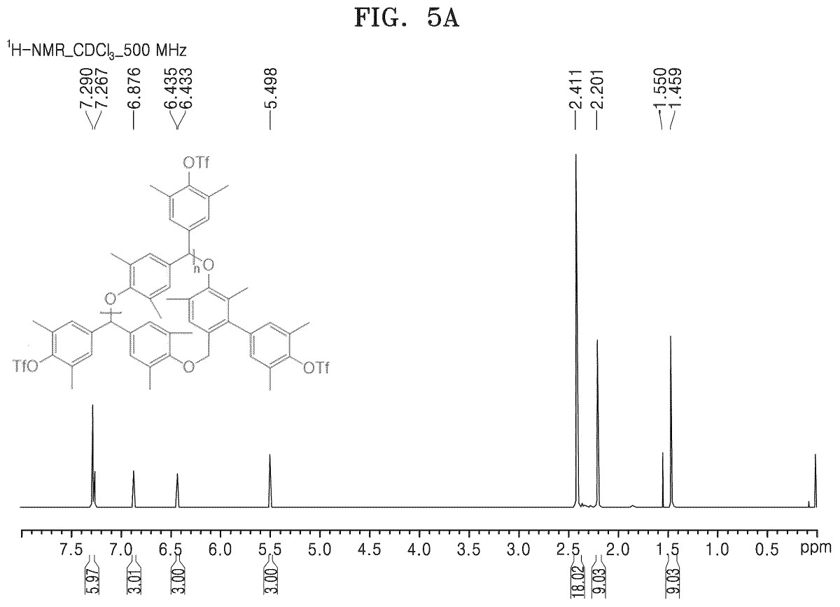

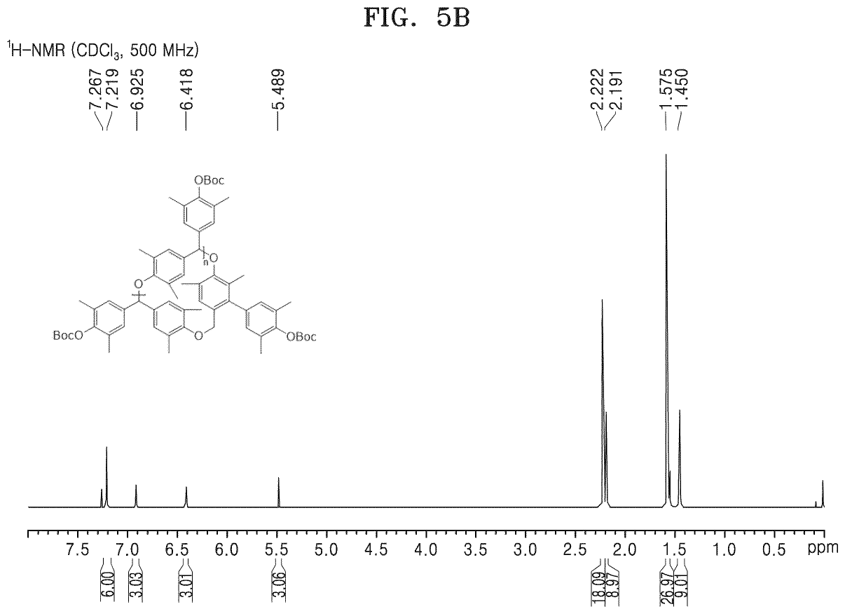

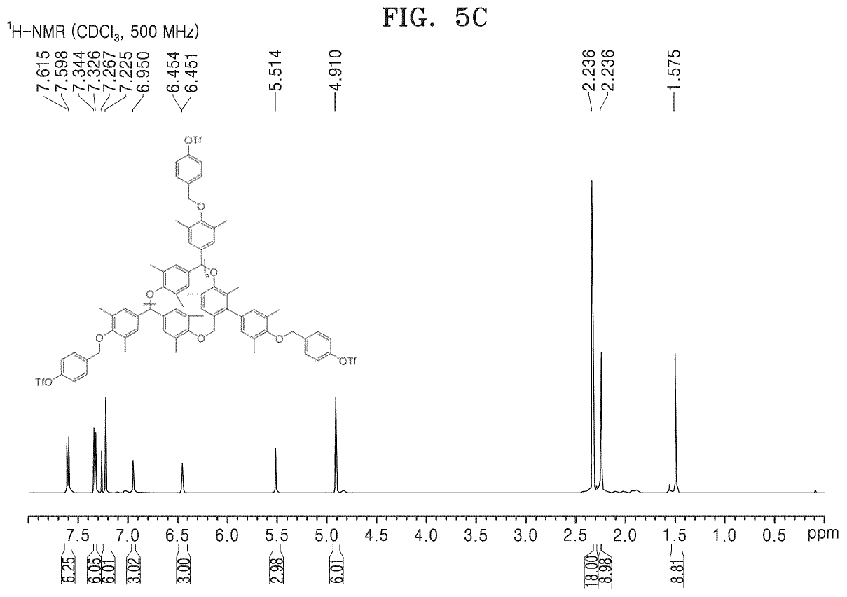

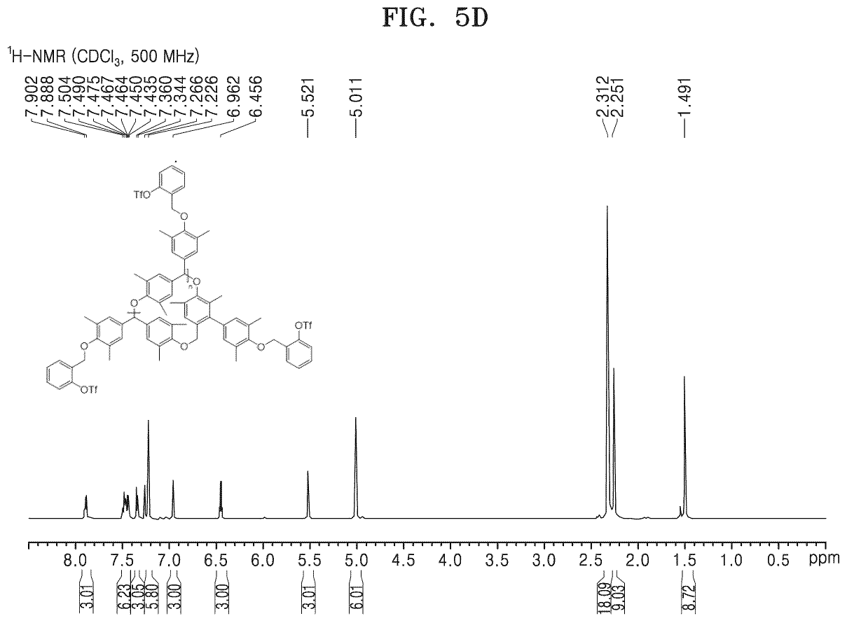

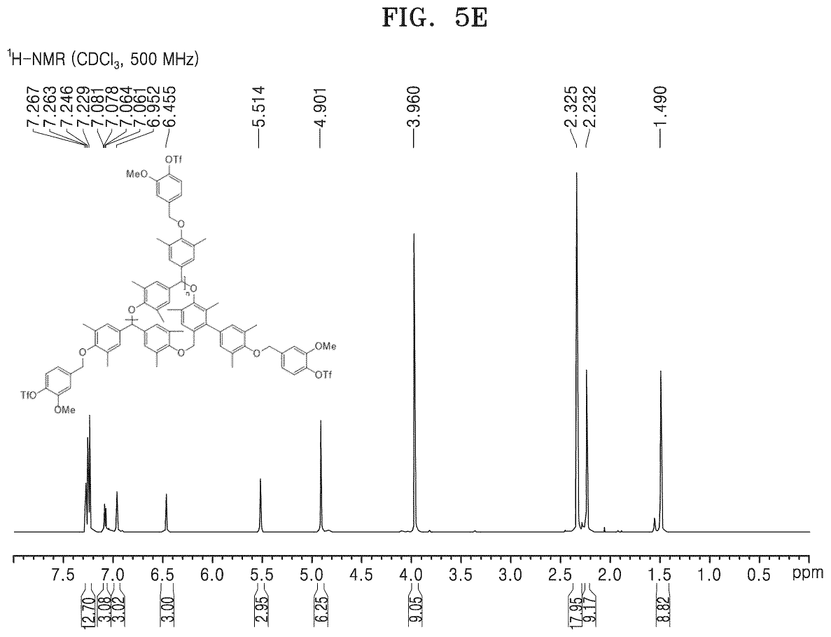

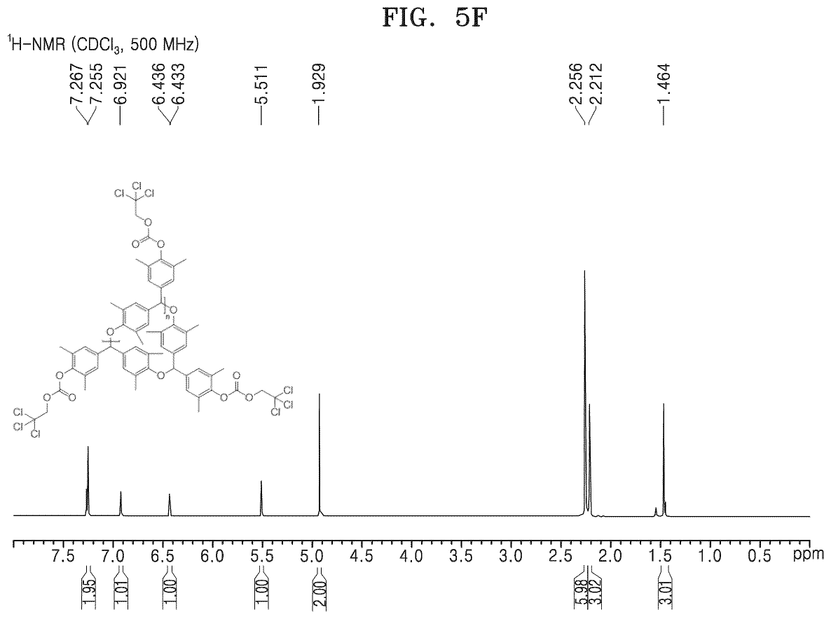

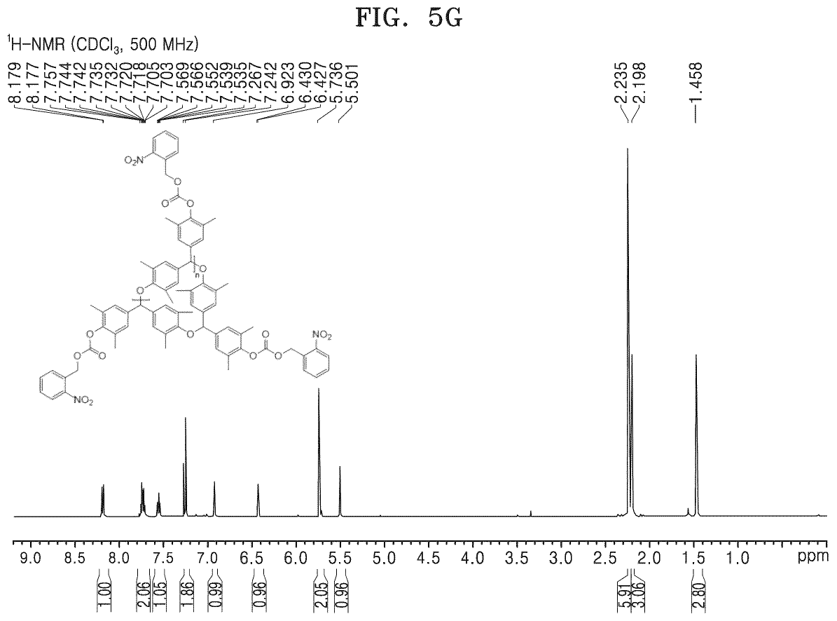

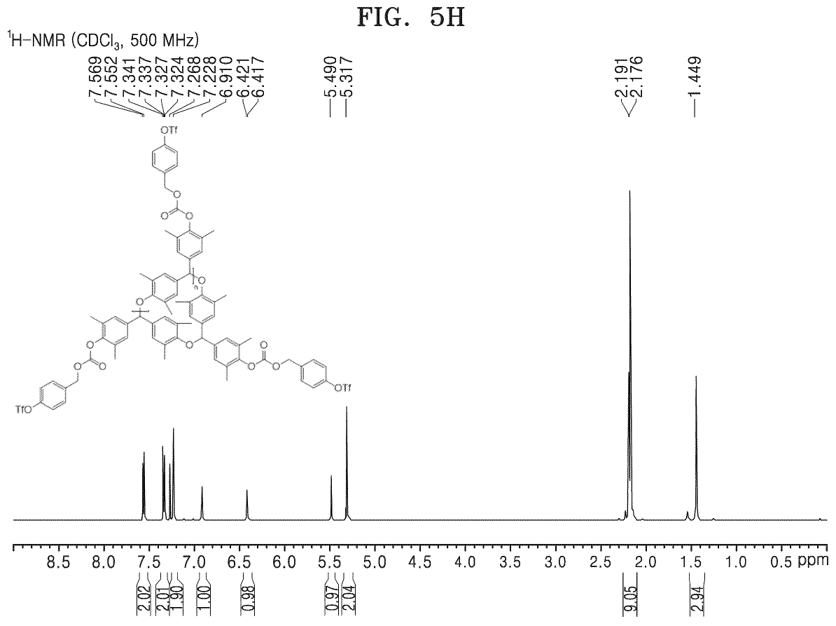

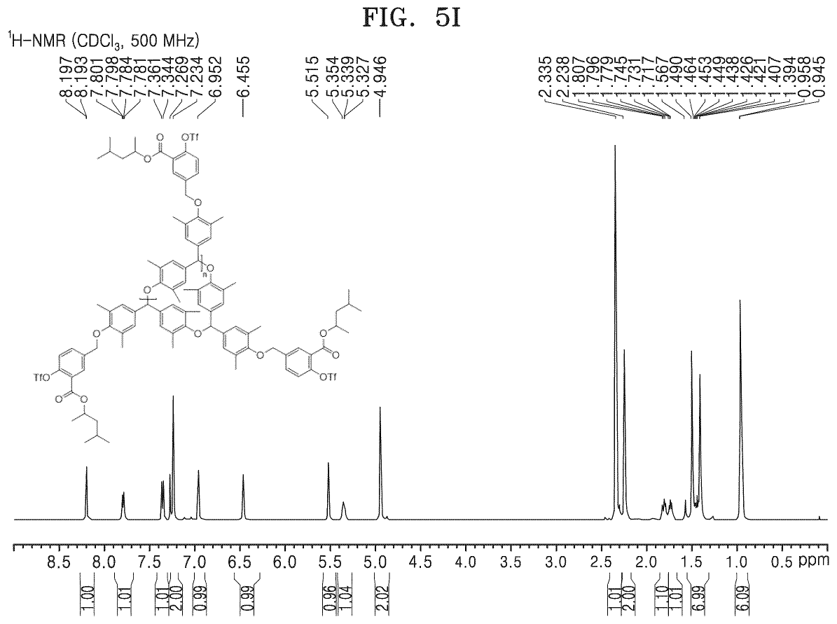

7.2 g (18.63 mmol) of compound QM-1 was dissolved in 18.5 mL of dichloromethane (DCM) and then cooled to a temperature of 0° C., and 0.053 g (0.373 mmol) of BF₃. Et₂O was added while performing stirring. The mixture was stirred at a temperature of 0° C. for 1 hour and then poured into 30 mL of MeOH to obtain a precipitate. DCM was evaporated under reduced pressure at a temperature of 30° C., a solid was filtered, and the precipitate was cleaned with a small amount of MeOH, suspended in 30 mL of MeOH at a temperature of 70° C. for 5 minutes, stirred, cooled to a temperature of 25° C., filtered, and then dried under reduced pressure at a temperature of 40° C. to obtain compound 1 as a white solid (5.69 g, yield of 79%). The obtained compound was confirmed through proton nuclear magnetic resonance (1^{H}) NMR and gel permeation chromatography (GPC). 1^{H} NMR analysis results are shown in FIG. 5A.

Mₙ=1.403 kDa, M, =1.430 kDa, PDI=1.02, thermogravimetric analysis (TGA): T_{d5%} wt. loss=248° C. differential scanning calorimetry (DSC): T_{g}/Tₘ>130° C.

### Synthesis Example 2: Synthesis of Compound 2

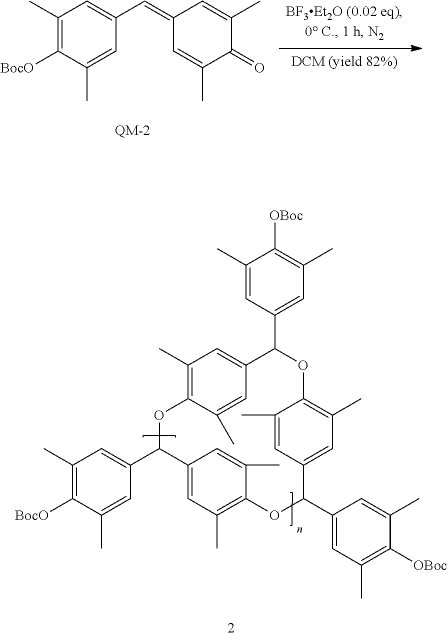

5.32 g (15 mmol) of compound QM-2 was dissolved in 15 mL of DCM and then cooled to a temperature of 0° C., and 0.053 g (0.3 mmol) of BF₃. Et₂O was added while performing stirring. The mixture was stirred at a temperature of 0° C. for 1 hour and then poured into 30 mL of MeOH to obtain a precipitate. DCM was evaporated under reduced pressure at a temperature of 30° C., a solid was filtered, and the precipitate was cleaned with a small amount of MeOH, suspended in 30 mL of MeOH at a temperature of 70° C. for 5 minutes, stirred, cooled to a temperature of 25° C., filtered, and then dried under reduced pressure at a temperature of 40° C. to obtain compound 2 as a white solid (4.36 g, yield of 82%). The obtained compound was confirmed through 1^{H} NMR and GPC. 1^{H} NMR analysis results are shown in FIG. 5B.

Mₙ=1.471 kDa, M, =1.519 kDa, PDI=1.03. TGA: T_{d5%} wt. loss=209° C. DSC: T_{g}/Tₘ>130° C.

### Synthesis Example 3: Synthesis of Compound 3

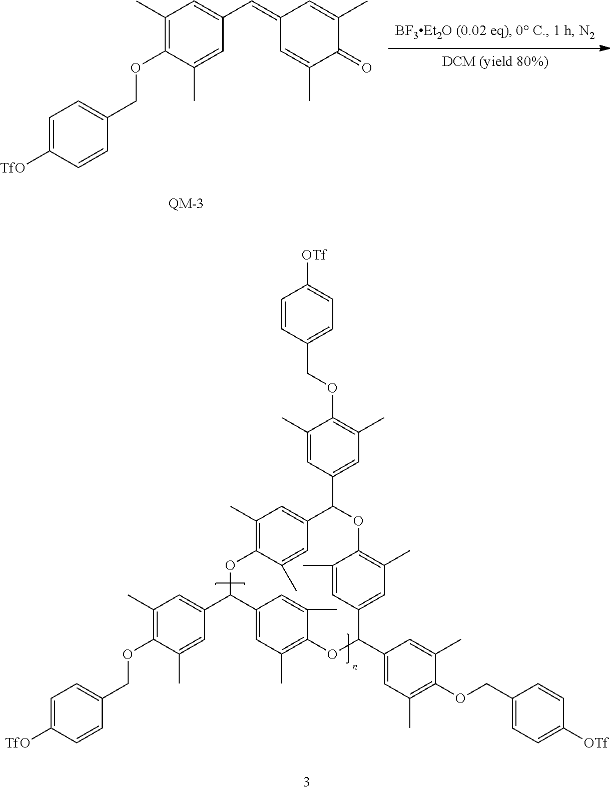

4 g (8.12 mmol) of compound QM-3 was dissolved in 8 mL of DCM and then cooled to a temperature of 0° C., and 0.023 g (0.16 mmol) of BF₃. Et₂O was added while performing stirring. The mixture was stirred at a temperature of 0° C. for 1 hour and then poured into 30 mL of MeOH to obtain a precipitate. DCM was evaporated under reduced pressure at a temperature of 30° C., a solid was filtered, and the precipitate was cleaned with a small amount of MeOH, suspended in 30 mL of MeOH at a temperature of 70° C. for 5 minutes, stirred, cooled to a temperature of 25° C., filtered, and then dried under reduced pressure at a temperature of 40° C. to obtain compound 3 as a white solid (3.2 g, yield of 80%). The obtained compound was confirmed through 1^{H} NMR and GPC. 1^{H} NMR analysis results are shown in FIG. 5C.

Mₙ=2.282 kDa, M_{w}=2.389 kDa, PDI=1.04. TGA: T_{d5%} wt. loss=275° C. DSC: T_{g}/Tₘ>120° C.

### Synthesis Example 4: Synthesis of Compound 4

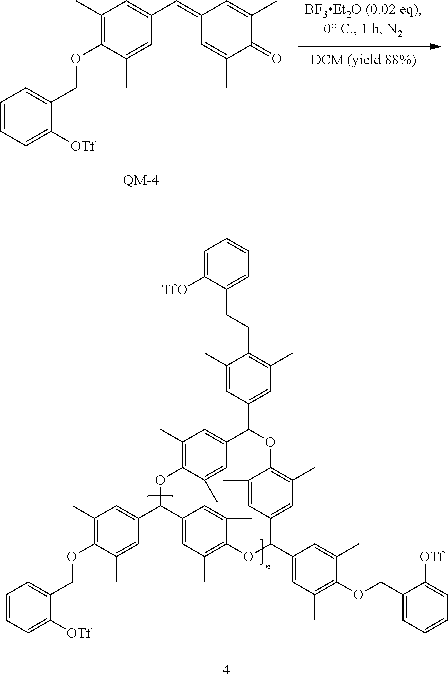

1.2 g (2.815 mmol) of compound QM-4 was dissolved in 2.8 mL of DCM and then cooled to a temperature of 0° C., and 0.008 g (0.0576 mmol) of BF₃. Et₂O was added while performing stirring. The mixture was stirred at a temperature of 0° C. for 1 hour and then poured into 30 mL of MeOH to obtain a precipitate. DCM was evaporated under reduced pressure at a temperature of 30° C., a solid was filtered, and the precipitate was cleaned with a small amount of MeOH, suspended in 30 mL of MeOH at a temperature of 70° C. for 5 minutes, stirred, cooled to a temperature of 25° C., filtered, and then dried under reduced pressure at a temperature of 40° C. to obtain compound 4 as a white solid (1.06 g, yield of 88%). The obtained compound was confirmed through 1^{H} NMR and GPC. 1^{H} NMR analysis results are shown in FIG. 5D.

Mₙ=1.792 kDa, M_{w}=1.872 kDa, PDI=1.04. TGA: T_{d5%} wt. loss=261° C. DSC: T_{g}/Tₘ>120° C.

### Synthesis Example 5: Synthesis of Compound 5

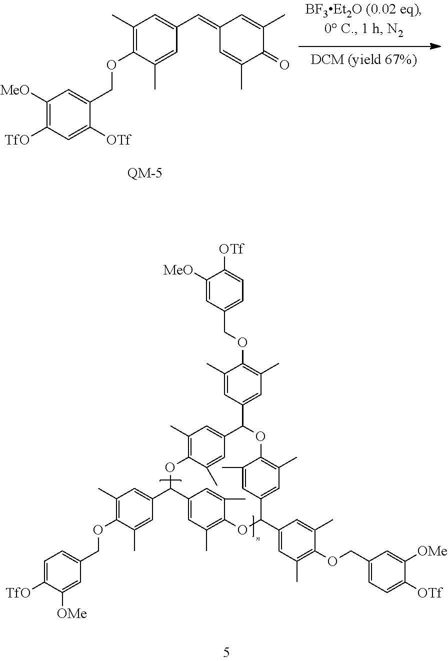

3.5 g (6.7 mmol) of compound QM-5 was dissolved in 6.7 mL of DCM and then cooled to a temperature of 0° C., and 0.019 g (0.13 mmol) of BF₃. Et₂O was added while performing stirring. The mixture was stirred at a temperature of 0° C. for 1 hour and then poured into 30 mL of MeOH to obtain a precipitate. DCM was evaporated under reduced pressure at a temperature of 30° C., a solid was filtered, and the precipitate was cleaned with a small amount of MeOH, suspended in 30 mL of MeOH at a temperature of 70° C. for 5 minutes, stirred, cooled to a temperature of 25° C., filtered, and then dried under reduced pressure at a temperature of 40° C. to obtain compound 5 as a white solid (2.33 g, yield of 66.6%). The obtained compound was confirmed through 1^{H} NMR and GPC. 1^{H} NMR analysis results are shown in FIG. 5E.

Mₙ=2.323 kDa, M_{w}=2.400 kDa, PDI=1.03. TGA: T_{d5%} wt. loss=273° C. DSC: T_{g}/Tₘ>120° C.

### Synthesis Example 6: Synthesis of Compound 6

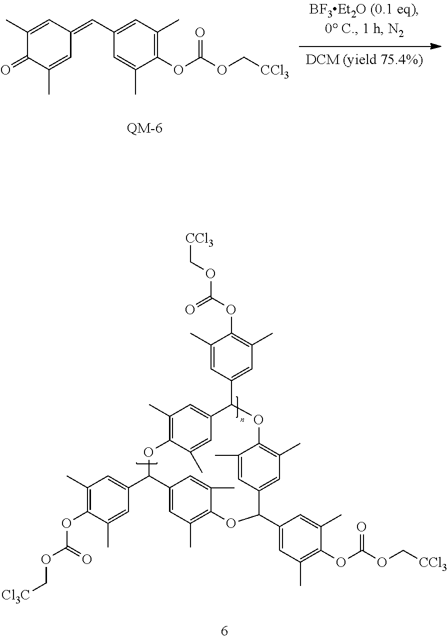

2.6 g (6.05 mmol) of compound QM-6 was dissolved in 8 mL of DCM and then cooled to a temperature of 0° C., and 0.086 g (0.605 mmol) of BF₃. Et₂O was added while performing stirring. The mixture was stirred at a temperature of 0° C. for 1 hour and then poured into 30 mL of MeOH to obtain a precipitate. DCM was evaporated under reduced pressure at a temperature of 30° C., a solid was filtered, and the precipitate was cleaned with a small amount of MeOH, suspended in 30 mL of MeOH at a temperature of 70° C. for 5 minutes, stirred, cooled to a temperature of 25° C., filtered, and then dried under reduced pressure at a temperature of 40° C. to obtain compound 6 as a white solid (1.96 g, yield of 75.4%). The obtained compound was confirmed through 1^{H} NMR and GPC. 1^{H} NMR analysis results are shown in FIG. 5F.

Mₙ=1.507 kDa, M_{w}=1.528 kDa, PDI=1.01. TGA: T_{d5%} wt. loss=317° C. DSC: T_{g}/Tₘ>120° C.

### Synthesis Example 7: Synthesis of Compound 7

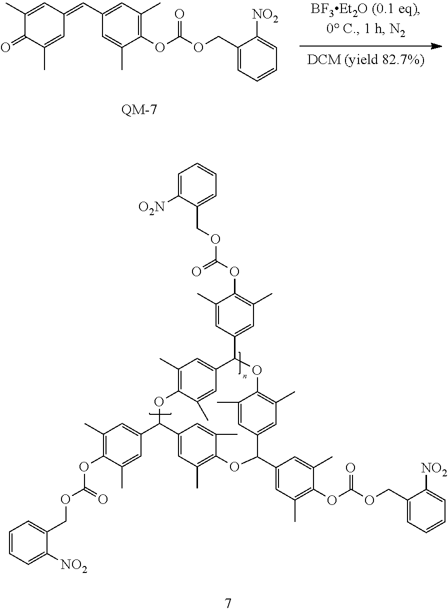

2.6 g (6 mmol) of compound QM-7 was dissolved in 12 mL of DCM and then cooled to a temperature of 0° C., and 0.085 g (0.6 mmol) of BF₃. Et₂O was added while performing stirring. The mixture was stirred at a temperature of 0° C. for 1 hour and then poured into 30 mL of MeOH to obtain a precipitate. DCM was evaporated under reduced pressure at a temperature of 30° C., a solid was filtered, and the precipitate was cleaned with a small amount of MeOH, suspended in 30 mL of MeOH at a temperature of 70° C. for 5 minutes, stirred, cooled to a temperature of 25° C., filtered, and then dried under reduced pressure at a temperature of 40° C. to obtain compound 7 as a white solid (2.15 g, yield of 82.7%). The obtained compound was confirmed through 1^{H} NMR and GPC. 1^{H} NMR analysis results are shown in FIG. 5G.

Mₙ=1.584 kDa, M_{w}=1.619 kDa, PDI=1.02. TGA: T_{d5%} wt. loss=276° C. DSC: T_{g}/Tₘ>120° C.

### Synthesis Example 8: Synthesis of Compound 8

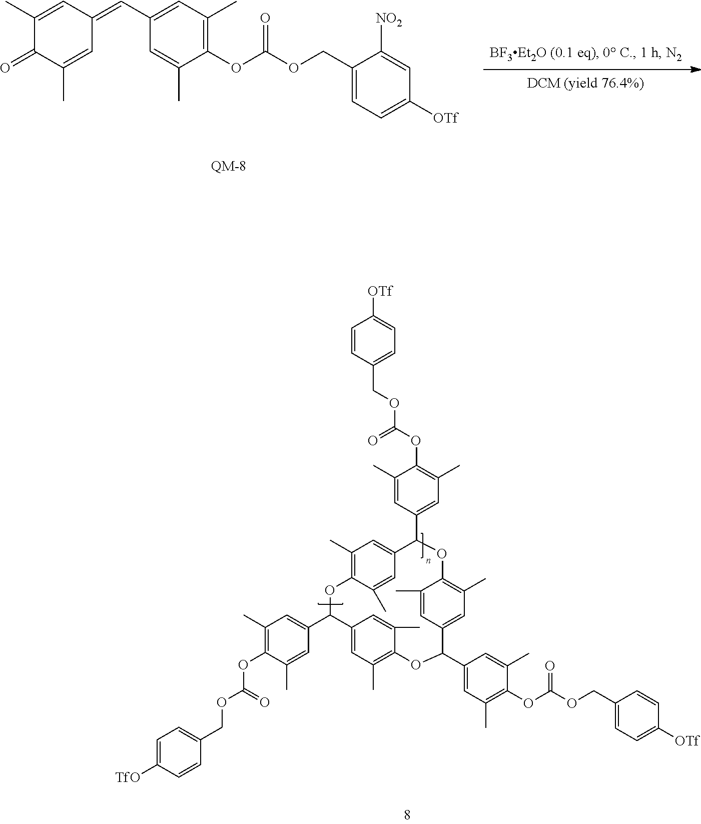

4.41 g (8.22 mmol) of compound QM-4 was dissolved in 12 mL of DCM and then cooled to a temperature of 0° C., and 0.117 g (0.822 mmol) of BF₃. Et₂O was added while performing stirring. The mixture was stirred at a temperature of 0° C. for 1 hour and then poured into 30 mL of MeOH to obtain a precipitate. DCM was evaporated under reduced pressure at a temperature of 30° C., a solid was filtered, and the precipitate was cleaned with a small amount of MeOH, suspended in 30 mL of MeOH at a temperature of 70° C. for 5 minutes, stirred, cooled to a temperature of 25° C., filtered, and then dried under reduced pressure at a temperature of 40° C. to obtain compound 8 as a white solid (3.37 g, yield of 76.4%). The obtained compound was confirmed through 1^{H} NMR and GPC. 1^{H} NMR analysis results are shown in FIG. 5H.

Mₙ=2.331 kDa, M_{w}=2.418 kDa, PDI=1.04. TGA: T_{d5%} wt. loss=316° C. DSC: T_{g}/Tₘ>120° C.

### Synthesis Example 9: Synthesis of Compound 9

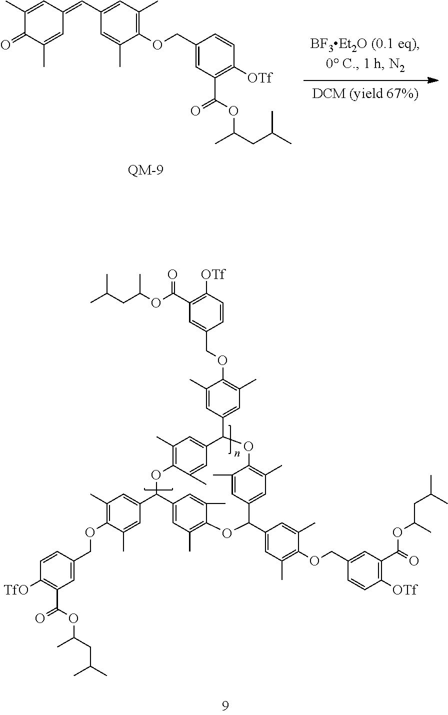

4.63 g (7.46 mmol) of compound QM-9 was dissolved in 40 mL of DCM and then cooled to a temperature of 0° C., and 0.106 g (0.746 mmol) of BF₃. Et₂O was added while performing stirring. The mixture was stirred at a temperature of 0° C. for 1 hour and then poured into 30 mL of MeOH to obtain a precipitate. DCM was evaporated under reduced pressure at a temperature of 30° C., a solid was filtered, and the precipitate was cleaned with a small amount of MeOH, suspended in 30 mL of MeOH at a temperature of 70° C. for 5 minutes, stirred, cooled to a temperature of 25° C., filtered, and then dried under reduced pressure at a temperature of 40° C. to obtain compound 9 as a white solid (3.1 g, yield of 67%). The obtained compound was confirmed through 1^{H} NMR and GPC. 1^{H} NMR analysis results are shown in FIG. 5I.

Mₙ=2.875 kDa, M_{w}=2.970 kDa, PDI=1.03. TGA: T_{d5%} wt. loss=285° C. DSC: T_{g}/Tₘ>120° C.

### Evaluation Example 1: Evaluation of Thermal Stability

About 5 mg to about 10 mg of each compound in Table 1 below was subjected to thermal analysis using TGA and DSC (N2 atmosphere, temperature range: from room temperature to 600° C. (10° C./min)-TGA, from room temperature to 600° C. (10° C./min)-DSC, pan type: Pt pan in disposable Al pan (TGA), disposable Al pan (DSC)). Results of T_{d5%} and glass transition temperature (T_{g}) versus melting point (Tₘ) of each compound are summarized in Table 1. During TGA analysis, a temperature at which a mass of a sample become 95% of an initial mass was denoted by T_{d5%}.

TABLE 1

| | Molecular | | | |
|---|---|---|---|---|
| | weight (M_{w}, | | | |
| Compound No. | g/mol) | PDI | T_{d 5%} (° C.) | Tg (° C.) |
| 1 | 1,430 | 1.02 | 248 | >130 |
| 2 | 1,519 | 1.03 | 209 | >130 |
| 3 | 2,389 | 1.04 | 275 | >120 |
| 4 | 1,872 | 1.04 | 285 | >130 |
| 5 | 2,400 | 1.03 | 273 | ~120 |
| 6 | 1,528 | 1.01 | 316 | >120 |
| 7 | 1,619 | 1.02 | 276 | >120 |
| 8 | 2,418 | 1.04 | 316 | >120 |
| 9 | 2,970 | 1.03 | 285 | >120 |

### Evaluation Example 2: Evaluation of Pattern Formation

Compounds shown in Tables 2 to 4 below were respectively dissolved in solvents shown in Tables 2 to 4 below at a temperature of 25° C. to prepare resist solutions in an amount of 1 wt % to 4 wt %. Before a resist was applied, a substrate was treated with hexamethyldisilazane (HMDS), which was a single layer of a resist primer, to secure excellent resist adhesion.

The resist solution was filtered with a 0.1 μm membrane filter, and then a silicon wafer treated with HMDS was spin-coated with the resist solution to form a thin film with a thickness of 40 nm to 50 nm. In order to remove an excess amount of a casting solvent, a hot plate was used to perform application at a temperature shown in Table 2 below for a time shown in Table 2 below, and then post-apply baking (PAB) was applied to the resist film. Next, the resist film was exposed to EUV radiation. PEB conditions were set at a temperature of 70° C. to 120° C. for 30 seconds to 180 seconds as shown in Table 2 below. The resist film was developed with 2.38 wt % of TMAH, cleaned with deionized water to remove a coating portion not exposed to EUV rays, and then dried to form a resist pattern.

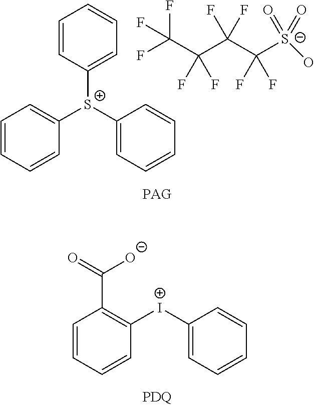

In Tables 2 to 4 below, Eₜₕ denotes an exposure amount at a point at which a thin film starts to be developed, and E₀ denotes an exposure amount at a point at which the thin film is completely developed (the thin film no longer becomes thinner). γ is a contrast curve and is a value calculated through Equation 1 or Equation 2 below. In this case, a positive tone and a negative tone are respectively calculated according to Equation 1 and Equation 2 below:

$$γ = {[ log \frac{{E}_{0}}{{E}_{th}} ]}^{- 1} \qquad Equation 1$$

$$γ = {\vert log ( \frac{{E}_{th}}{{E}_{0}} ) \vert}^{- 1} \qquad Equation 2$$

TABLE 2

| | Solvent, | PAB T | PEB T | | | |
|---|---|---|---|---|---|---|
| | (conc. | (° C.)/time | (° C.)/time | EUV dose (mJ/cm²) | | Contrast, |
| Compound | wt %) | (s) | (s) | Eₜₕ | E₀ | γ |
| 1 | HA^{(a)} (2) | 110/60 | 90/60 | 12.6 | 14.3 | 17.5 |
| 3 | PGMEA^{(c)} | 110/60 | 90/60 | 1.7 | 2.9 | 3.7 |
| | (2.25) | | | | | |
| 3 + PDQ (10 wt %) | CPN^{(b)} (2) | 110/60 | 90/60 | 11.8 | 14.7 | 10.5 |
| 3 + PDQ (30 wt %) | CPN (2.25) | 110/60 | 90/60 | 25 | 32 | 9.3 |
| 5 | PGMEA (2.5) | 100/60 | 90/60 | 2.1 | 4.1 | 3.4 |
| 5 + PDQ (10 wt %) | PGMEA (2.5) | 100/60 | 90/60 | 7.5 | 11.8 | 5.1 |

TABLE 3

| | Solvent, | PAB T | PEB T | | | |
|---|---|---|---|---|---|---|
| | (conc. | (° C.)/time | (° C.)/time | EUV dose (mJ/cm²) | | Contrast, |
| Compound | wt %) | (s) | (s) | Eₜₕ | E₀ | γ |
| 2 + PAG (30 wt %) | CPN (2) | 110/60 | 70/30 | 8.0 | 11.2 | 7 |
| 2 + PAG (20 wt %) | CPN (2) | 110/60 | 90/60 | 7.0 | 8.5 | 11.5 |

TABLE 4

| | Solvent, | PAB T | PEB T | EUV dose (mJ/cm²) | | | | | |
|---|---|---|---|---|---|---|---|---|---|
| | (conc. | (° C.)/time | (° C.)/time | Positive tone | | Negative tone | | Contrast, | |
| Compound | wt %) | (s) | (s) | ^{P}Eₜₕ | ^{P}E₀ | ^{N}Eₜₕ | ^{N}E₀ | ^{PT}γ | ^{NT}γ |
| 8 | PGMEA (2) | 110/60 | 120/180 | 3.5 | 14.4 | 14.4 | 20 | 1.6 | 7 |
| 9 | PGMEA (2) | 110/60 | 90/60 | 5.7 | 7.5 | 15 | 19.2 | 8.3 | 9.3 |

(a) HA—hexyl acetate,
(b) CPN—cyclopentanone,
(c) PGMEA—propylene glycol methyl ether acetate

Referring to Tables 2 to 4, it may be seen that a photoreactive compound according to some example embodiments exhibit small Eₜₕ and/or E₀ values and/or a large g value, and thus it has been confirmed that a resist composition including the photoreactive compound has improved (e.g., excellent) photosensitivity.

In view of at least the above, some example embodiments of the inventive concepts may provide a resist composition having improved sensitivity and providing a pattern with improved resolution, thereby enabling the formation of a semiconductor device having improved pattern resolutions, thereby enabling miniaturization of semiconductor devices with improved device reliability based on the reduced likelihood of device defects due to reduced likelihood of defects resulting from low pattern resolution.

It should be understood that example embodiments described herein should be considered in a descriptive sense only and not for purposes of limitation. Descriptions of features or aspects within each example embodiment should typically be considered as available for other similar features or aspects in other example embodiments. While some example embodiments have been described with reference to the drawings, it will be understood by those of ordinary skill in the art that various changes in form and details may be made therein without departing from the spirit and scope as defined by the following claims.

What is claimed is:

1. A photoreactive compound represented by Formula 1: 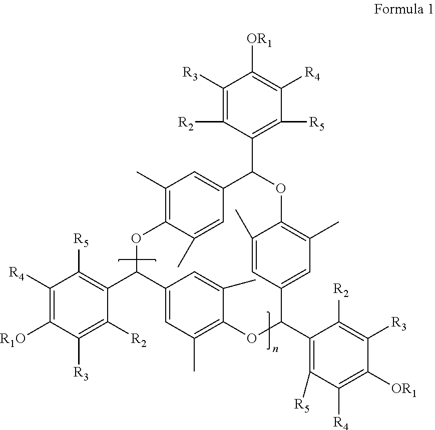
wherein, in Formula 1,
R₁ is a photosensitive group or an acid-sensitive protecting group,
R₂ to R₅ are each independently hydrogen; deuterium; a halogen; a cyano group; a nitro group; a hydroxy group; a C₁-C₃₀ monovalent hydrocarbon group optionally containing a heteroatom; a C₁-C₃₀ alkoxy group; a C₁-C₃₀ aryloxy group;
a photosensitive group; or an acid-sensitive protecting group, and
n is an integer from 1 to 10.

2. The photoreactive compound of claim 1, wherein the photosensitive group is reactive to visible light, ultraviolet (UV) rays, deep ultraviolet (DUV) rays, extreme ultraviolet (EUV) rays, electron beams (EBs), and/or X-rays.

3. The photoreactive compound of claim 1, wherein the photosensitive group or the acid-sensitive protecting group is a group represented by any one of -Tf, -Boc, and Formulas 2-1 to 2-25: 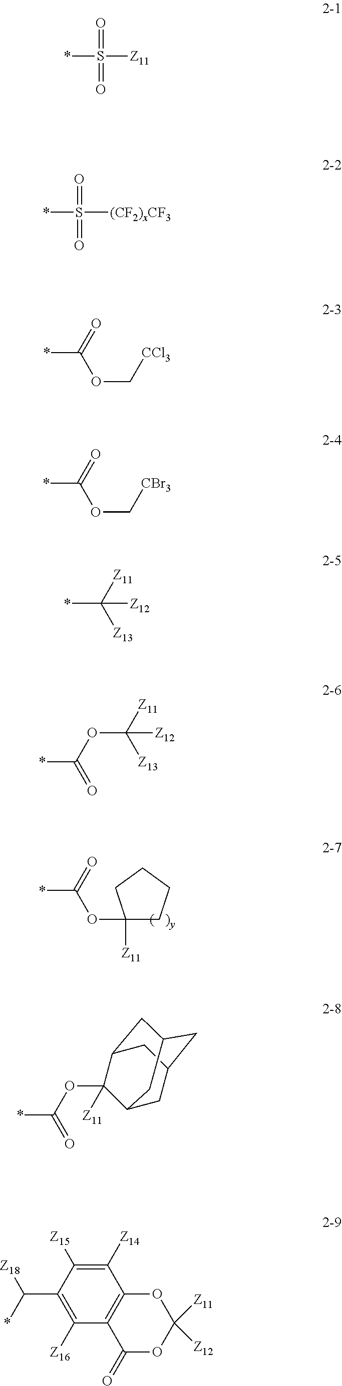 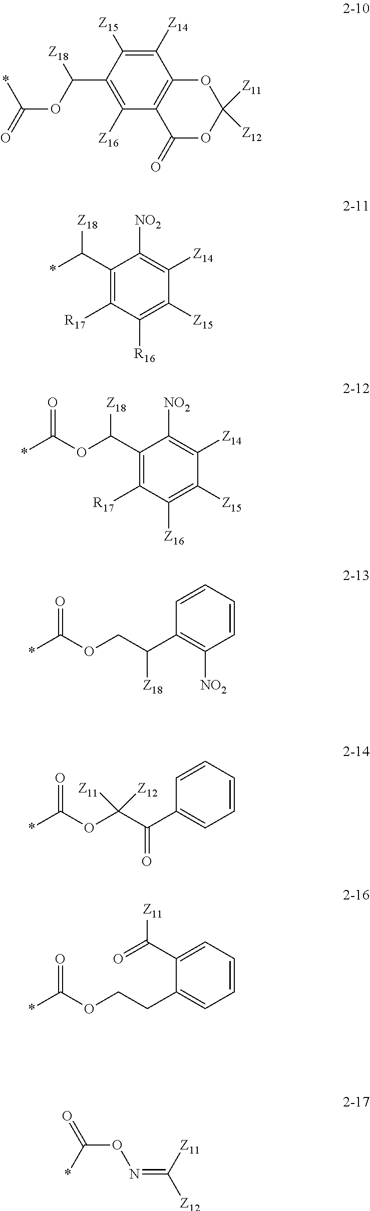 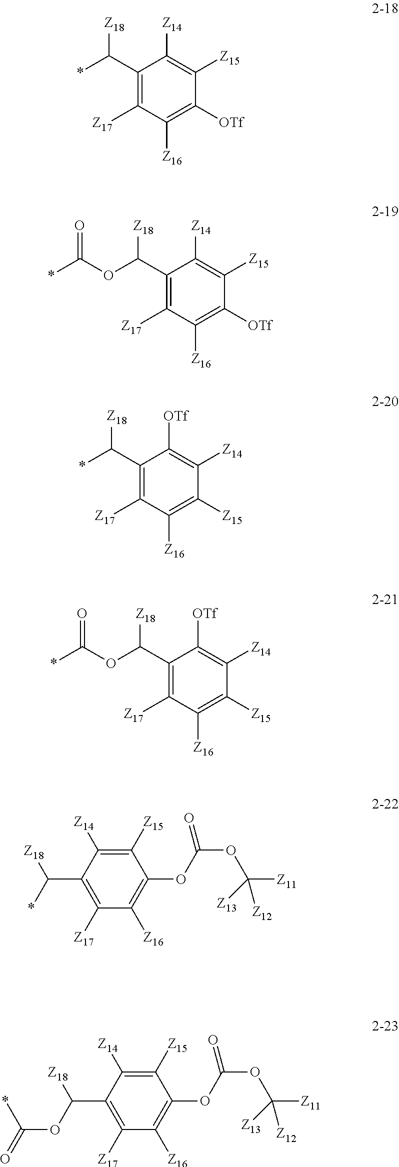 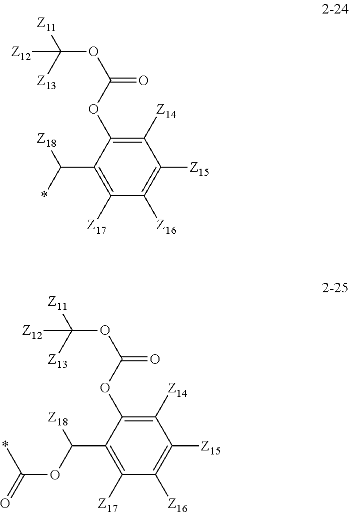
wherein, in Formulas 2-1 to 2-25,
Z₁₁ to Z₁₈ are each independently hydrogen; deuterium; a halogen; a cyano group; a nitro group; a hydroxy group; a C₁-C₃₀ monovalent hydrocarbon group optionally containing a heteroatom and unsubstituted or substituted with a substituent; a C₁-C₃₀ alkoxy group unsubstituted or substituted with a substituent; a C₁-C₃₀ aryloxy group unsubstituted or substituted with a substituent; —CF₃; —OTf; —OMs; —OTos; or —OBoc,
R₁₆ and R₁₇ are each independently hydrogen; deuterium; a halogen; a cyano group; a nitro group; a hydroxy group; a C₁-C₃₀ monovalent hydrocarbon group optionally containing a heteroatom and unsubstituted or substituted with a substituent; a C₁-C₃₀ alkoxy group unsubstituted or substituted with a substituent; a C₁-C₃₀ aryloxy group unsubstituted or substituted with a substituent; —CF₃; —OTf; —OMs; —OTos; or —OBoc,
Tf is a triflate (trifluoromethanesulfonate) group,
Ms is a mesyl group,
Tos is a tosyl group,
Boc is a tert-butoxycarbonyl group,
Ph is a phenyl group,
x is an integer from 1 to 10,
y is an integer from 1 to 10, and
* is a binding site with an adjacent atom of Formula 1.

4. The photoreactive compound of claim 3, wherein, in Formulas 2-1 to 2-25, Z₁₁ to Z₁₃ are each independently selected from Formulas 3-1 to 3-36: 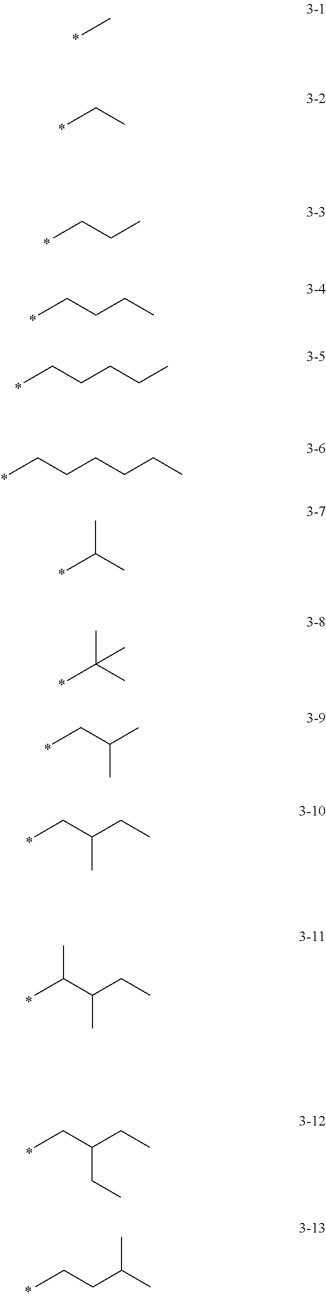 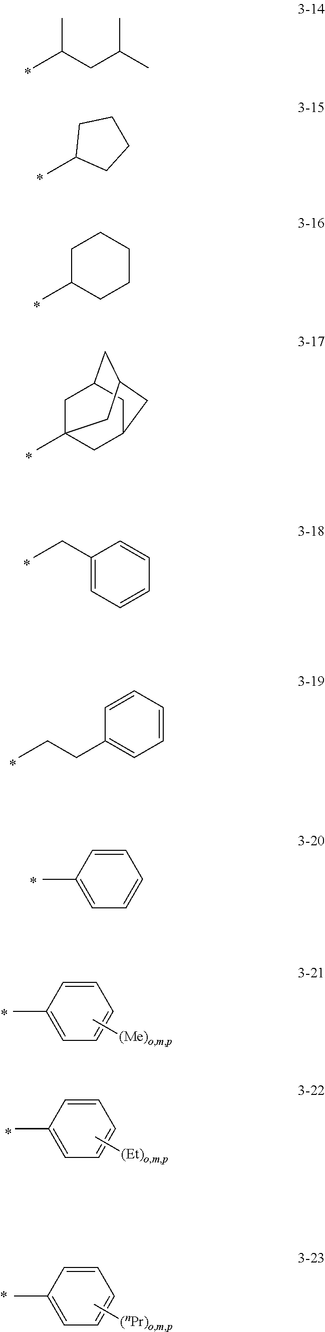 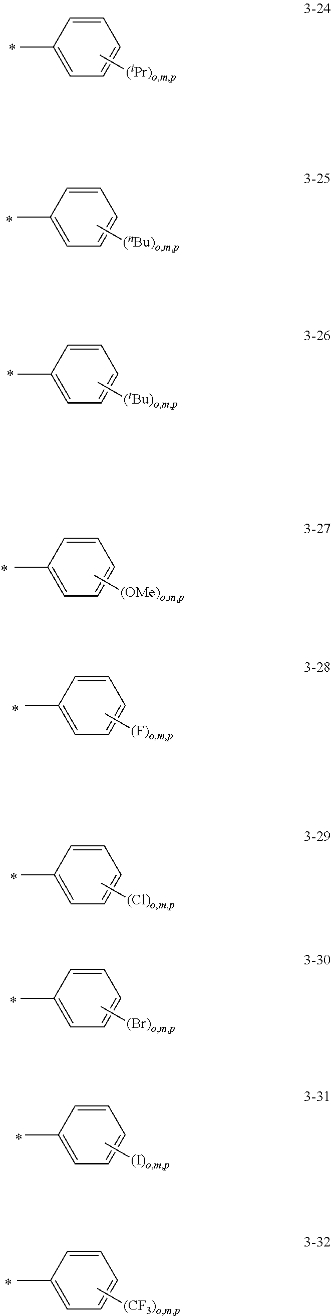 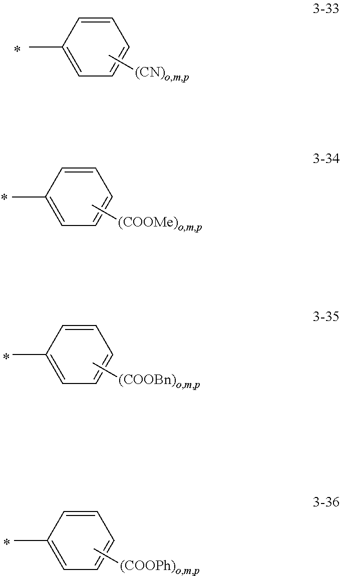
wherein, in Formulas 3-1 to 3-36,
* is a binding site with an adjacent atom,
o, m, p is one of an ortho position, a meta position, or a para position,
Me is a methyl group,
Et is an ethyl group,
ⁿPr is an n-propyl group,
ⁱPr is an isopropyl group,
ⁿBu is an n-butyl group,
^{t}Bu is a tert-butyl group,
Bn is a benzyl group, and
Ph is a phenyl group.

5. The photoreactive compound of claim 3, wherein, in Formulas 2-1 to 2-25, Z₁₄ to Z₁₇ and R₁₆ to R₁₇ are selected from Formulas 4-1 to 4-46: 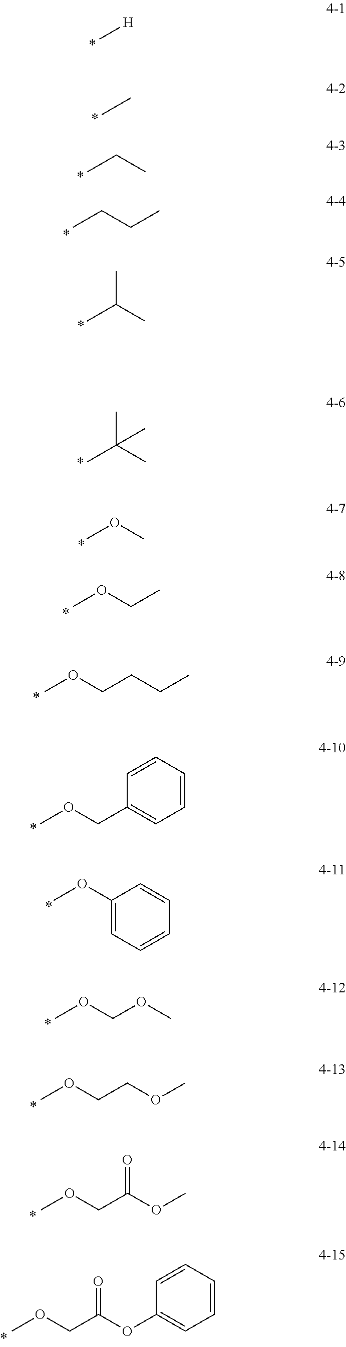 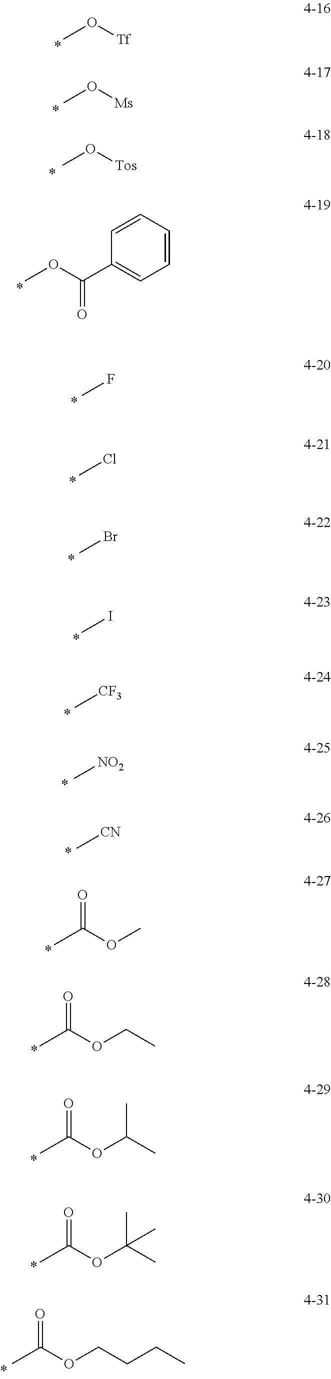 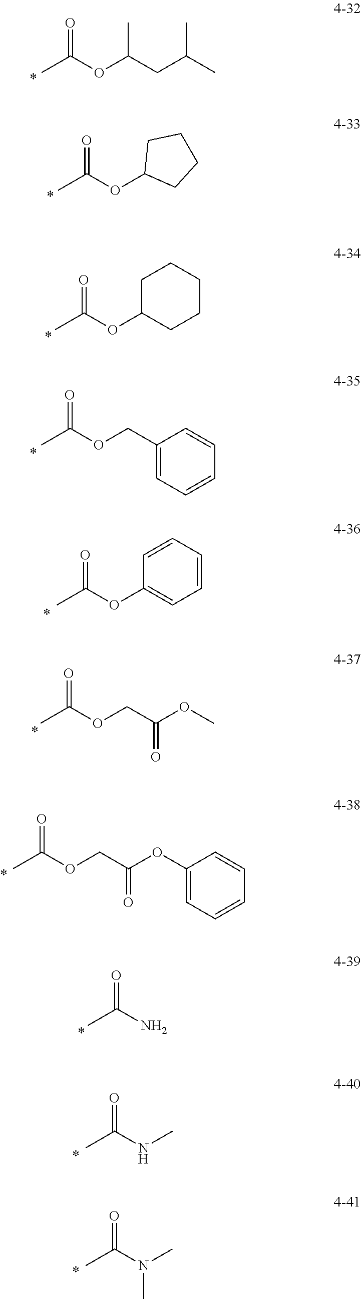 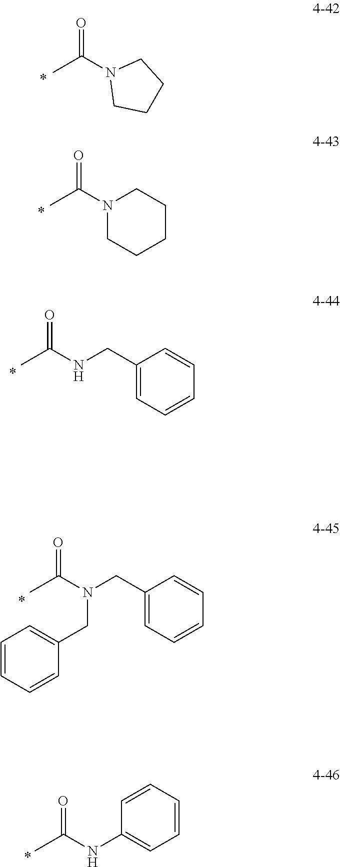
wherein, in Formulas 4-1 to 4-46,
* is a binding site with an adjacent atom,
Tf is a triflate (trifluoromethanesulfonate) group,
Ms is a mesyl group, and
Tos is a tosyl group.

6. The photoreactive compound of claim 3, wherein, in Formulas 2-1 to 2-25, Z₁₈ is selected from Formulas 5-1 to 5-10: 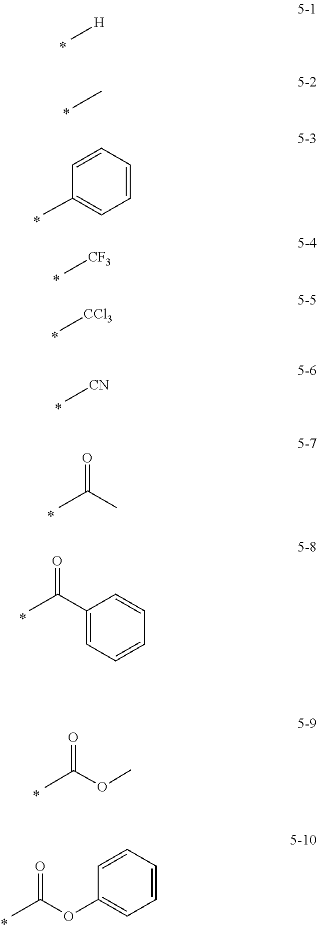
wherein, in Formulas 5-1 to 5-10, * is a binding site with an adjacent atom.

7. The photoreactive compound of claim 1, wherein the photoreactive compound has a weight average molecular weight of about 1,000 g/mol to about 3,000 g/mol.

8. The photoreactive compound of claim 1, wherein the photoreactive compound has a polydispersity index (PDI) of about 1 to about 1.5.

9. The photoreactive compound of claim 1, wherein the photoreactive compound has a glass transition temperature of 100° C. or more.

10. The photoreactive compound of claim 1, wherein the photoreactive compound has a 5% mass loss temperature (T_{d5%}) of 180° C. or more.

11. The photoreactive compound of claim 1, wherein, in Formula 1, n is an integer from 1 to 5.

12. The photoreactive compound of claim 1, wherein the photoreactive compound represented by Formula 1 is selected from Group I:

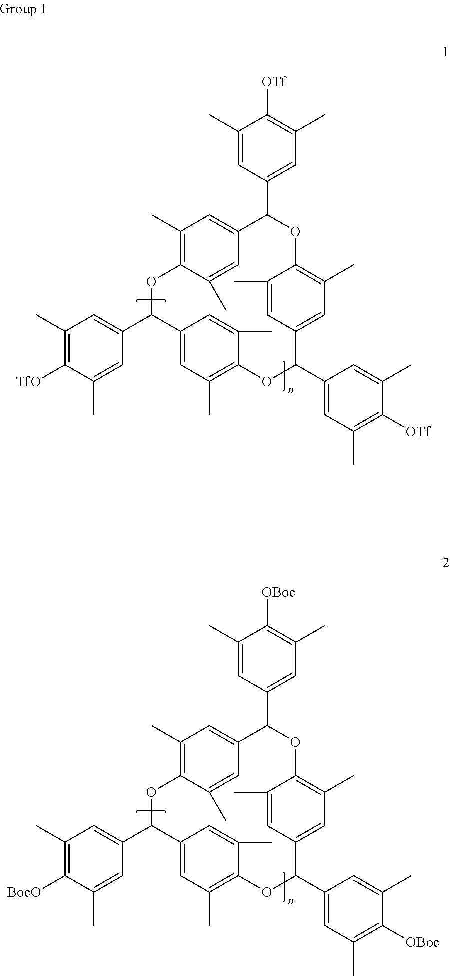

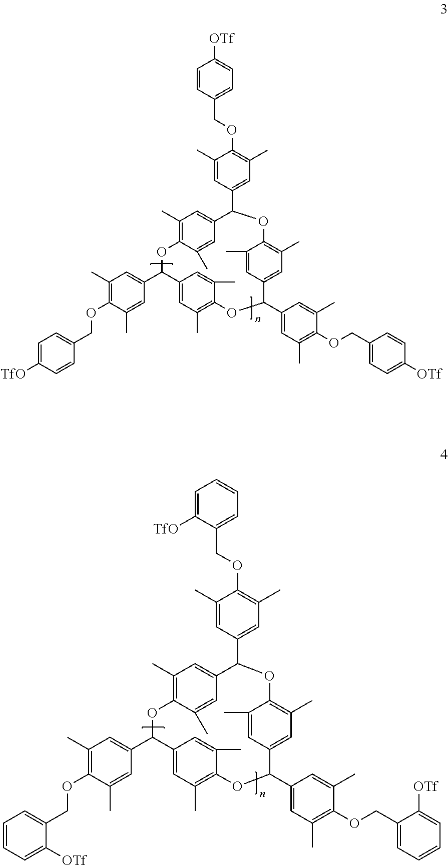

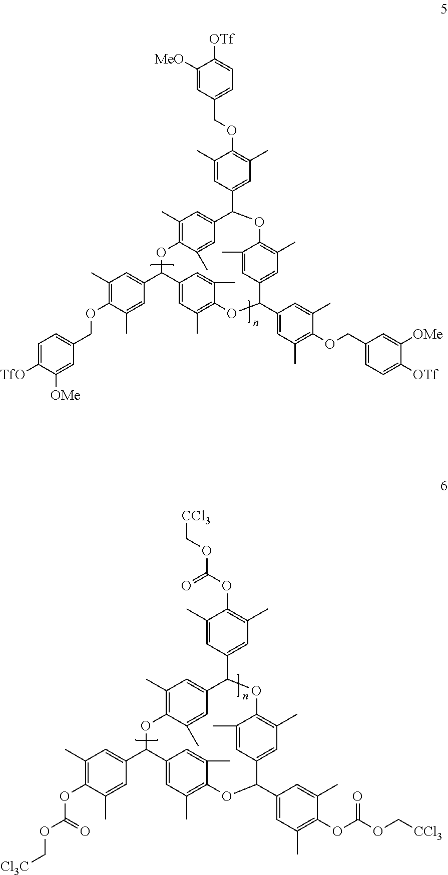

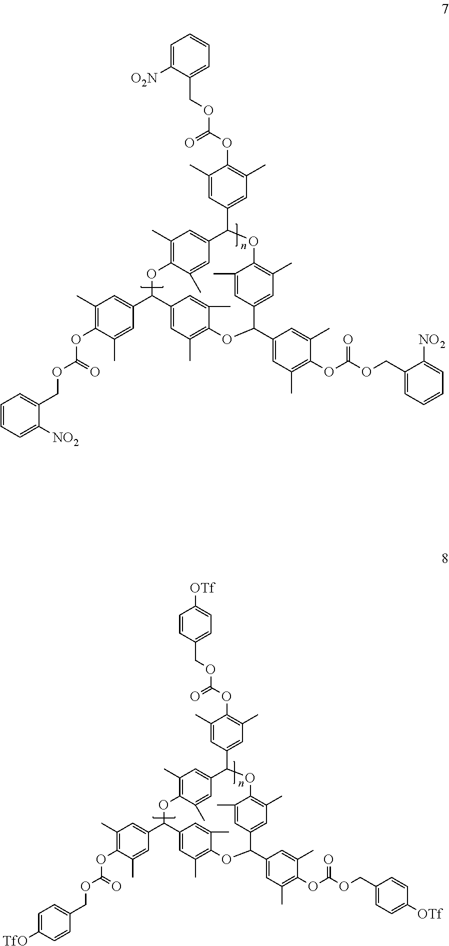

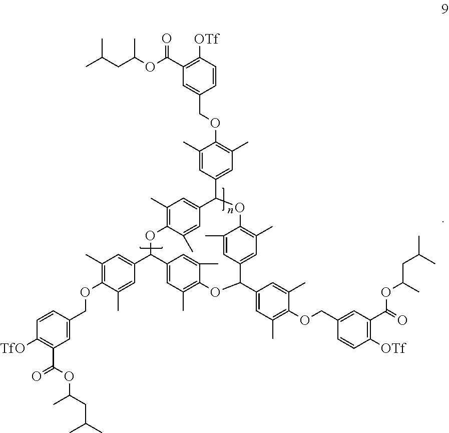

13. A resist composition, comprising:
the photoreactive compound of claim 1; and
an organic solvent.

14. The resist composition of claim 13, further comprising a photoacid generator, a quencher, or any combination thereof.

15. The resist composition of claim 13, wherein the resist composition does not comprise any photoacid generators.

16. The resist composition of claim 13, wherein the resist composition is a positive tone resist composition.

17. The resist composition of claim 13, wherein the resist composition is a non-chemically amplified (non-CA) resist composition.

18. The resist composition of claim 13, wherein the photoreactive compound is included in the resist composition in an amount of about 0.1 parts by weight to about 50 parts by weight with respect to 100 parts by weight of the resist composition.

19. A pattern formation method, comprising:
applying the resist composition of claim 13 onto a substrate to form a resist film;
exposing at least a portion of the resist film to high-energy rays to form an exposed resist film; and
developing the exposed resist film based on using a developer.

20. The pattern formation method of claim 19, wherein the exposing is performed based on irradiating ultraviolet (UV) rays, deep ultraviolet (DUV) rays, extreme ultraviolet (EUV) rays, and/or electron beams (EBs).
